(19) United States
(12) Patent Application Publication
(10) Pub. No.: US 2025/0130427 A1
(43) Pub. Date: Apr. 24, 2025

(54) Electronic Device

(71) Applicant: Semiconductor Energy Laboratory Co., Ltd., Kanagawa-ken (JP)

(72) Inventors: Daiki NAKAMURA, Atsugi, Kanagawa (JP); Hisao IKEDA, Zama, Kanagawa (JP); Ryo HATSUMI, Hadano, Kanagawa (JP); Takeya HIROSE, Atsugi, Kanagawa (JP)

(73) Assignee: Semiconductor Energy Laboratory Co., Ltd., Kanagawa-ken (JP)

(21) Appl. No.: 18/834,445

(22) PCT Filed: Jan. 23, 2023
(86) PCT No.: PCT/IB2023/050526

§ 371 Date: Jul. 30, 2024

(30) Foreign Application Priority Data
Feb. 4, 2022 (JP) 2022-016142

(51) Int. Cl. G02B 27/01; H04N 13/344; H10K 59/35

(52) U.S. Cl. CPC G02B 27/0172; H10K 59/353; G02B 2027/0134; G02B 2207/101; H04N 13/344

(57) ABSTRACT

An electronic device providing a high sense of immersion is provided. An electronic device with low power consumption is provided. A first display device includes a plurality of first pixels. The first pixel includes a light-emitting element exhibiting green. A second display device includes a plurality of second pixels. The second pixel includes a light-emitting element exhibiting red and a light-emitting element exhibiting blue. Each of the first display device and the second display device has a function of displaying a first image and a second image. The first display device is provided at such a position that the first image is reflected by the first half mirror and enters an eyepiece lens. The second display device is provided at such a position that the second image passes through the first half mirror and enters the eyepiece lens. The first image and the second image are each presented through the eyepiece lens.

### TECHNICAL FIELD

One embodiment of the present invention relates to a display device. One embodiment of the present invention relates to an electronic device including a display device.

Note that one embodiment of the present invention is not limited to the above technical field. Examples of a technical field of one embodiment of the present invention disclosed in this specification and the like include a semiconductor device, a display device, a light-emitting apparatus, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

As electronic devices provided with display devices for augmented reality (AR) or virtual reality (VR), wearable electronic devices are becoming widespread. Examples of wearable electronic devices include a head-mounted display (HMD) and a glasses-type electronic device.

When using an electronic device such as an HMD with a short distance between a display portion and a user, the user is likely to perceive pixels and strongly feels granularity, whereby the sense of immersion and realistic sensation of AR or VR might be diminished. Thus, an HMD is preferably provided with a display device that has minute pixels so that the pixels are not perceived by the user. Patent Document 1 discloses a method in which an HMD including minute pixels is achieved by using minute transistors capable of high-speed driving.

[Reference]

[Patent Document]

[Patent Document 1] Japanese Published Patent Application No. 2000-2856

### SUMMARY OF THE INVENTION

### Problems to be Solved by the Invention

An object of one embodiment of the present invention is to provide an electronic device providing a high sense of immersion. Another object is to provide an electronic device with high display quality. Another object is to provide an electronic device capable of displaying an image with a higher resolution as the image is closer to a gaze point. Another object is to provide an electronic device with low power consumption. Another object is to provide an electronic device that can be manufactured at low cost. Another object is to provide an electronic device with a novel structure.

An object of one embodiment of the present invention is to provide a display device with a novel structure or an electronic device with a novel structure. An object of one embodiment of the present invention is to at least alleviate at least one of problems of the conventional technique.

Note that the description of these objects does not preclude the existence of other objects. Note that one embodiment of the present invention does not need to achieve all of these objects. Note that objects other than these can be derived from the description of the specification, the drawings, the claims, and the like.

### Means for Solving the Problems

One embodiment of the present invention is an electronic device including a first display device, a second display device, a first half mirror, and an eyepiece lens. The first display device includes a plurality of first pixels. Each of the plurality of first pixels includes a light-emitting element exhibiting a first color. The second display device includes a plurality of second pixels. Each of the plurality of second pixels includes a light-emitting element exhibiting a second color and a light-emitting element exhibiting a third color. The first color is one of green and blue, the second color is red, and the third color is the other of green and blue. The first display device has a function of displaying a first image. The second display device has a function of displaying a second image. The first display device is provided at such a position that the first image is reflected by the first half mirror and enters the eyepiece lens. The second display device is provided at such a position that the second image passes through the first half mirror and enters the eyepiece lens. The first image is presented through the eyepiece lens. The second image is presented, through the eyepiece lens, to be superimposed on the first image.

Another embodiment of the present invention is an electronic device including a first display device, a second display device, a first half mirror, and an eyepiece lens. The first display device includes a plurality of first pixels. Each of the plurality of first pixels includes a light-emitting element exhibiting a first color. The second display device includes a plurality of second pixels. Each of the plurality of second pixels includes a light-emitting element exhibiting a second color and a light-emitting element exhibiting a third color. The first color is one of green and blue, the second color is red, and the third color is the other of green and blue. The first display device has a function of displaying a first image. The second display device has a function of displaying a second image. The first display device is provided at such a position that the first image passes through the first half mirror and enters the eyepiece lens. The second display device is provided at such a position that the second image is reflected by the first half mirror and enters the eyepiece lens. The first image is presented through the eyepiece lens. The second image is presented, through the eyepiece lens, to be superimposed on the first image.

In the above structure, a pixel density of the first pixels in the first display device is preferably equal to a pixel density of the second pixels in the second display device.

In the above structure, the pixel density of the first pixels in the first display device is preferably higher than or equal to 1000 ppi and lower than or equal to 20000 ppi.

Another embodiment of the present invention is an electronic device including a first display device, a second display device, a first half mirror, and an eyepiece lens. The first display device includes a plurality of first subpixels arranged in a matrix. Each of the plurality of first subpixels includes a light-emitting element exhibiting a first color. The second display device includes a plurality of second subpixels arranged in a matrix and a plurality of third subpixels arranged in a matrix. Each of the plurality of second subpixels includes a light-emitting element exhibiting a second color. Each of the plurality of third subpixels includes a light-emitting element exhibiting a third color. The first color is one of green and blue, the second color is red, and the third color is the other of green and blue. A pixel density of the first subpixels in the first display device is higher than a pixel density of the second subpixels in the second display device. In the second display device, the second subpixels and the third subpixels are alternately arranged in a horizontal direction and alternately arranged in a vertical direction in a plan view. The first display device has a function of displaying a first image. The second display device has a function of displaying a second image. The first display device is provided at such a position that the first image is reflected by the first half mirror and enters the eyepiece lens. The second display device is provided at such a position that the second image passes through the first half mirror and enters the eyepiece lens. The first image is presented through the eyepiece lens. The second image is presented through the eyepiece lens.

Another embodiment of the present invention is an electronic device including a first display device, a second display device, a first half mirror, and an eyepiece lens. The first display device includes a plurality of first subpixels arranged in a matrix. Each of the plurality of first subpixels includes a light-emitting element exhibiting a first color. The second display device includes a plurality of second subpixels arranged in a matrix and a plurality of third subpixels arranged in a matrix. Each of the plurality of second subpixels includes a light-emitting element exhibiting a second color. Each of the plurality of third subpixels includes a light-emitting element exhibiting a third color. The first color is one of green and blue, the second color is red, and the third color is the other of green and blue. A pixel density of the first subpixels in the first display device is higher than a pixel density of the second subpixels in the second display device. In the second display device, the second subpixels and the third subpixels are alternately arranged in a horizontal direction and alternately arranged in a vertical direction in a plan view. The first display device has a function of displaying a first image. The second display device has a function of displaying a second image. The first display device is provided at such a position that the first image passes through the first half mirror and enters the eyepiece lens. The second display device is provided at such a position that the second image is reflected by the first half mirror and enters the eyepiece lens. The first image is presented through the eyepiece lens. The second image is presented through the eyepiece lens.

In the above structure, the first image and the second image superimposed on each other are preferably presented as a third image through the eyepiece lens, and in the third image, the first subpixel preferably includes a first region overlapping with one of the plurality of second subpixels, a second region overlapping with one of the plurality of third subpixels, and a third region overlapping neither the one of the plurality of second subpixels nor the one of the plurality of third subpixels.

Another embodiment of the present invention is an electronic device including a first display device, a second display device, a first half mirror, and an eyepiece lens. The first display device includes a first display portion. The second display device includes a second display portion and a third display portion. The third display portion is provided to surround at least part of the second display portion in a plan view. The first display portion includes a plurality of first pixels. Each of the plurality of first pixels includes a light-emitting element exhibiting a first color. The second display portion includes a plurality of second pixels. Each of the plurality of second pixels includes a light-emitting element exhibiting a second color and a light-emitting element exhibiting a third color. The third display portion includes a plurality of third pixels. Each of the plurality of third pixels includes a light-emitting element exhibiting the first color, a light-emitting element exhibiting the second color, and a light-emitting element exhibiting the third color. The first color is one of green and blue, the second color is red, and the third color is the other of green and blue. A pixel density of the third pixels in the third display portion is lower than a pixel density of the first pixels in the first display portion and a pixel density of the second pixels in the second display portion. The first display portion has a function of displaying a first image. The second display portion has a function of displaying a second image. The third display portion has a function of displaying a third image. The first display device is provided at such a position that the first image is reflected by the first half mirror and enters the eyepiece lens. The second display device is provided at such a position that the second image and the third image pass through the first half mirror and enter the eyepiece lens. The first image is presented through the eyepiece lens. The second image is presented, through the eyepiece lens, to be superimposed on the first image. The third image is presented through the eyepiece lens. The third image presented through the eyepiece lens is presented in a region surrounding the first image presented through the eyepiece lens and the second image presented through the eyepiece lens.

Another embodiment of the present invention is an electronic device including a first display device, a second display device, a first half mirror, and an eyepiece lens. The first display device includes a first display portion. The second display device includes a second display portion and a third display portion. The third display portion is provided to surround at least part of the second display portion in a plan view. The first display portion includes a plurality of first pixels. Each of the plurality of first pixels includes a light-emitting element exhibiting a first color. The second display portion includes a plurality of second pixels. Each of the plurality of second pixels includes a light-emitting element exhibiting a second color and a light-emitting element exhibiting a third color. The third display portion includes a plurality of third pixels. Each of the plurality of third pixels includes a light-emitting element exhibiting the first color, a light-emitting element exhibiting the second color, and a light-emitting element exhibiting the third color. The first color is one of green and blue, the second color is red, and the third color is the other of green and blue. A pixel density of the third pixels in the third display portion is lower than a pixel density of the first pixels in the first display portion and a pixel density of the second pixels in the second display portion. The first display portion has a function of displaying a first image. The second display portion has a function of displaying a second image. The third display portion has a function of displaying a third image. The first display device is provided at such a position that the first image passes through the first half mirror and enters the eyepiece lens. The second display device is provided at such a position that the second image and the third image are reflected by the first half mirror and enter the eyepiece lens. The first image is presented through the eyepiece lens. The second image is presented, through the eyepiece lens, to be superimposed on the first image. The third image is presented through the eyepiece lens. The third image presented through the eyepiece lens is presented in a region surrounding the first image presented through the eyepiece lens and the second image presented through the eyepiece lens.

In the above structure, it is preferable that the pixel density of the first pixels in the first display portion be higher than or equal to 1000 ppi and lower than or equal to 20000 ppi, and the pixel density of the third pixels in the third display portion be higher than or equal to 50 ppi and lower than 1000 ppi.

### Effect of the Invention

According to one embodiment of the present invention, an electronic device providing a high sense of immersion can be provided. Alternatively, an electronic device with high display quality can be provided. Alternatively, an electronic device capable of displaying an image with a higher resolution as the image is closer to a gaze point can be provided. Alternatively, an electronic device with low power consumption can be provided. Alternatively, an electronic device that can be manufactured at low cost can be provided. Alternatively, an electronic device with a novel structure can be provided.

According to one embodiment of the present invention, a display device with a novel structure or an electronic device with a novel structure can be provided. According to one embodiment of the present invention, at least one of problems of the conventional technique can be at least alleviated.

Note that the description of these effects does not preclude the existence of other effects. Note that one embodiment of the present invention does not need to have all of these effects. Note that effects other than these can be derived from the description of the specification, the drawings, the claims, and the like.

### BRIEF DESCRIPTION OF THE DRAWINGS

FIG. 1A and FIG. 1B are diagrams illustrating a structure example of an electronic device.

FIG. 2A and FIG. 2B are diagrams illustrating structure examples of an electronic device.

FIG. 3A and FIG. 3B are diagrams illustrating structure examples of an electronic device.

FIG. 4A and FIG. 4B are diagrams illustrating a structure example of an electronic device.

FIG. 5A and FIG. 5B are diagrams illustrating structure examples of display devices.

FIG. 6A and FIG. 6B are diagrams illustrating structure examples of display devices.

FIG. 7A and FIG. 7B are diagrams illustrating structure examples of display devices.

FIG. 8A and FIG. 8B are diagrams illustrating structure examples of display devices.

FIG. 9A, FIG. 9B, and FIG. 9C are diagrams illustrating structure examples of display devices.

FIG. 10 is a diagram illustrating a structure example of display devices.

FIG. 11A to FIG. 11D are cross-sectional views illustrating structure examples of display devices.

FIG. 12A and FIG. 12B are diagrams illustrating a structure example of an electronic device.

FIG. 13A is a plan view illustrating a structure example of a display portion. FIG. 13B is a diagram illustrating a structure example of an electronic device.

FIG. 14 is a cross-sectional view illustrating a structure example of a display device.

FIG. 15A to FIG. 15C are cross-sectional views illustrating structure examples of a display device.

FIG. 16A to FIG. 16C are cross-sectional views illustrating structure examples of a display device.

FIG. 17A and FIG. 17B are cross-sectional views illustrating structure examples of a display device.

FIG. 18A and FIG. 18B are block diagrams illustrating structure examples of display devices.

FIG. 19 is a perspective view illustrating a structure example of a display device.

FIG. 20 is a perspective view illustrating a structure example of a display module.

FIG. 21 is a cross-sectional view illustrating a structure example of a display device.

FIG. 22 is a cross-sectional view illustrating a structure example of a display device.

FIG. 23 is a cross-sectional view illustrating a structure example of a display device.

FIG. 24 is a cross-sectional view illustrating a structure example of a display device.

FIG. 25 is a cross-sectional view illustrating a structure example of a display device.

FIG. 26 is a cross-sectional view illustrating a structure example of a display device.

FIG. 27 is a perspective view illustrating a structure example of a display device.

FIG. 28A is a cross-sectional view illustrating a structure example of a display device. FIG. 28B and FIG. 28C are cross-sectional views illustrating structure examples of transistors.

FIG. 29A to FIG. 29F are cross-sectional views illustrating structure examples of a light-emitting element.

FIG. 30A to FIG. 30C are cross-sectional views illustrating structure examples of a light-emitting element.

### MODE FOR CARRYING OUT THE INVENTION

Embodiments are described below with reference to the drawings. Note that the embodiments can be implemented with many different modes, and it will be readily understood by those skilled in the art that modes and details thereof can be changed in various ways without departing from the spirit and scope thereof. Thus, the present invention should not be interpreted as being limited to the following description of the embodiments.

Note that in structures of the invention described below, the same portions or portions having similar functions are denoted by the same reference numerals in different drawings, and description thereof is not repeated. The same hatching pattern is used for portions having similar functions, and the portions are not denoted by specific reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that ordinal numbers such as “first” and “second” in this specification and the like are used in order to avoid confusion among components and do not limit the number of components.

In this specification and the like, a display panel that is one embodiment of a display device has a function of displaying (outputting) an image or the like on (to) a display surface. Therefore, the display panel is one embodiment of an output device.

In this specification and the like, a structure where a connector such as an FPC (Flexible Printed Circuit) or a TCP (Tape Carrier Package) is attached to a substrate of a display panel, or a structure where an IC is mounted on the substrate by a COG (Chip On Glass) method or the like is referred to as a display panel module or a display module, or simply as a display panel or the like in some cases.

### Embodiment 1

In this embodiment, electronic devices of embodiments of the present invention will be described.

The electronic device of one embodiment of the present invention is an electronic device that can be worn on a head. The electronic device can present a three-dimensional image using parallax to a user. That is, the electronic device can be used as a VR device. Furthermore, the electronic device may have a function of displaying scenery in front of the user, which is captured with a camera (this function is also referred to as a video see-through function). Moreover, the electronic device can perform what is called AR display in which an image synthesized with the scenery in front of the user is displayed.

The electronic device includes two display devices (a first display device and a second display device) and an eyepiece lens. The user can see an image obtained by synthesizing a first image displayed by the first display device and a second image displayed by the second display device through the eyepiece lens.

Specifically, the electronic device preferably includes a half mirror. One of the first image and the second image passes through the half mirror to reach the eyepiece lens, and the other is reflected by the half mirror to reach the eyepiece lens. By placing the first display device, the second display device, the half mirror, and the eyepiece lens in this manner, the user can see, through the eyepiece lens, an image obtained by superimposing (synthesizing) the first image and the second image.

Note that in this specification and the like, the viewing angle of the electronic device refers to a range where the user can see an image through an optical member such as a lens. Unless otherwise specified, the description “viewing angle” denotes a viewing angle in the horizontal direction. Note that the term “viewing angle” includes the viewing angle with one eye and the viewing angle with both eyes, and generally the viewing angle with both eyes is larger than that with one eye. The viewing angle is also referred to as an FOV (Field of View) in some cases.

More specific examples of the electronic device are described below with reference to drawings.

### Structure Example 1

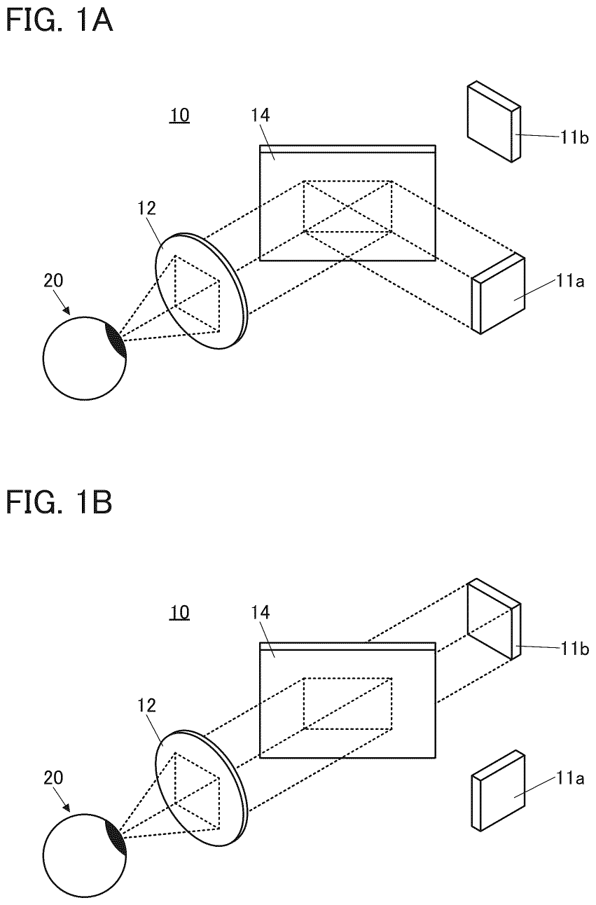

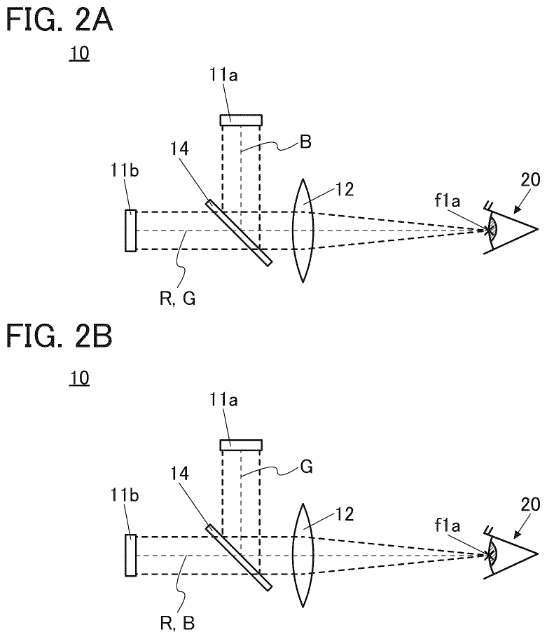

FIG. 1A and FIG. 1B are each a perspective view illustrating some components of an electronic device 10 of one embodiment of the present invention. The electronic device 10 includes a display device 11a, a display device 11b, a lens 12, and a half mirror 14. FIG. 1A illustrates the tracks of light (an image) emitted from the display device 11a, and FIG. 1B illustrates the tracks of light emitted from the display device 11b. FIG. 1A and FIG. 1B each schematically illustrate a user's eye 20 in the vicinity of the lens 12. FIG. 2A is a schematic view of the electronic device 10 seen in a direction perpendicular to the optical axis of the lens 12.

The display device 11a includes, for example, an element emitting light of a first color selected from red (R), green (G), and blue (B). The display device 11b includes, for example, an element emitting light of a second color selected from red, green, and blue and an element emitting light of a third color selected from red, green, and blue. The display device 11a and the display device 11b each have a function of displaying an image. An image displayed by the display device 11a includes the first color selected from red, green, and blue. An image displayed by the display device 11b includes light of the second color selected from red, green, and blue and light of the third color selected from red, green, and blue. Note that the second color is preferably different from the first color, and the third color is preferably different from both the first color and the second color. In the example illustrated in FIG. 2A, the first color is blue, the second color is red, and the third color is green.

Note that the colors of light emitted from the elements included in the display device 11a and the display device 11b are not limited to red, green, and blue. For example, an element emitting cyan, magenta, yellow, yellowish green, violet, bluish violet, orange, white, infrared, or ultraviolet light may be included. The colors included in images displayed by the display device 11a and the display device 11b are not limited to red, green, and blue. For example, cyan, magenta, yellow, yellowish green, violet, bluish violet, orange, white, infrared, or ultraviolet light may be included.

The display device 11a can be expressed as a display device performing monochromatic display. A display device performing monochromatic display does not require separate formation of pixels for different colors, for example, and thus can be manufactured through a simplified process. It is also unnecessary to place subpixels corresponding to different colors in one pixel, thereby enabling a small pixel area and a high resolution of the display device. It is also unnecessary to place a plurality of subpixels in one pixel, thereby increasing the aperture ratio of the pixel. Increasing the aperture ratio can reduce the power consumption of the display device 11a in some cases. Furthermore, increasing the aperture ratio can reduce luminance per area and extend the lifetime of the display device 11a in some cases.

An image displayed by the display device 11a and an image displayed by the display device 11b pass through the lens 12 and enter the user's eye 20 to be visually recognized. The image displayed by the display device 11a and the image displayed by the display device 11b preferably have the same size when entering the user's eye 20. The image displayed by the display device 11a and the image displayed by the display device 11b are preferably visually recognized by the user's eye 20 as images with the same size. The image displayed by the display device 11a and the image displayed by the display device 11b are preferably superimposed on each other so that one image is formed and enters the user's eye 20. The image displayed by the display device 11a and the image displayed by the display device 11b are preferably visually recognized by the user's eye 20 as a superimposed image.

The electronic device of one embodiment of the present invention includes a plurality of display devices and displays images displayed by the plurality of the display devices to be superimposed on each other, thereby providing an image with a higher resolution than an image displayed by one display device.

The electronic device of one embodiment of the present invention includes a plurality of display devices and displays images displayed by the plurality of the display devices to be superimposed on each other; accordingly, the manufacturing process of the display device can be simplified as compared with the case where an image with the same pixel density is displayed by only one display device. This can improve the yield of the electronic device. In addition, the manufacturing cost of the electronic device can be reduced.

The electronic device 10 can display images of different colors by the display device 11a and the display device 11b, and can display an image obtained by superimposing the image displayed by the display device 11a and the image displayed by the display device 11b. Superimposing the image displayed by the display device 11a and the image displayed by the display device 11b on each other enables display of a full-color image, for example. The electronic device 10 includes a circuit for supplying image data to the display device 11a and the display device 11b. The circuit for supplying image data to the display devices will be described in detail later. The image data supplied from the circuit to the display devices is not necessarily composed of grayscale values of three colors, and may be composed of grayscale values of two or fewer colors or may be composed of grayscale values of four or more colors.

In the electronic device of one embodiment of the present invention, image data includes, for example, a grayscale value representing the luminance of red light (a red grayscale value), a grayscale value representing the luminance of green light (a green grayscale value), and a grayscale value representing the luminance of blue light (a blue grayscale value). In the electronic device 10 illustrated in FIG. 2A, for example, the blue grayscale value is supplied to the display device 11a, and the red grayscale value and the green grayscale value are supplied to the display device 11b. The image data is data representing a display image.

FIG. 2B illustrates an example of the electronic device where the display device 11a includes a display element emitting green (G) light and the display device 11b includes a display element emitting red (R) light and a display element emitting blue (B) light. An image displayed by the display device 11a illustrated in FIG. 2B includes green (G) light, and an image displayed by the display device 11b includes red (R) light and blue (B) light. In the electronic device 10 illustrated in FIG. 2B, for example, the green grayscale value is supplied to the display device 11a, and the red grayscale value and the blue grayscale value are supplied to the display device 11b. The display device 11a includes a plurality of pixels arranged in a matrix, and each of the pixels includes a subpixel corresponding to the first color. The display device 11b includes a plurality of pixels arranged in a matrix, and each of the pixels includes a subpixel corresponding to the second color and a subpixel corresponding to the third color.

The number of subpixels included in the pixel of the display device 11a is smaller than the number of subpixels included in the pixel of the display device 11b, for example. In the case where the pixel density of the display device 11a and the pixel density of the display device 11b are the same, the area of the subpixel included in the pixel of the display device 11a can be larger than the area of the subpixel included in the pixel of the display device 11b.

Alternatively, the area of the subpixel included in the pixel of the display device 11a and the area of the subpixel included in the pixel of the display device 11b can be the same. In such a case, the area of the pixel of the display device 11a can be smaller than the area of the pixel of the display device 11b because of a smaller number of subpixels included in the pixel of the display device 11a. Accordingly, the pixel density of the display device 11a can be higher than the pixel density of the display device 11b.

In the case where image data includes image data corresponding to red, image data corresponding to green, and image data corresponding to blue, the resolution of the image data corresponding to any one of the colors may be higher than the resolution of the image data corresponding to the other colors. Note that the image data may include image data corresponding to white in addition to red, green, and blue.

For example, when the number of pixels of a color with a high luminosity factor is increased, the resolution of an image displayed by the electronic device 10 can be increased by the color with a high luminosity factor.

Note that the color represented by the image data is not limited to red, green, blue, and white, and can be cyan, magenta, yellow, yellowish green, violet, bluish violet, orange, infrared, ultraviolet, or the like.

The display device 11a and the display device 11b each include a display portion. The display portions of the display device 11a and the display device 11b preferably have the same size. When the display portions have the same size, the structure of an optical system of the electronic device 10 can be simplified. For example, the number of components used for the optical system can be reduced. The display portion included in the display device includes a plurality of pixels arranged in a matrix, for example. In another possible expression, the display device includes a plurality of pixels and the plurality of pixels are arranged in a matrix in the display portion. In another possible expression, the display device includes a plurality of pixels and the plurality of pixels are arranged in a matrix to form the display portion.

The display portions of the display device 11a and the display device 11b may have different sizes. In the case where the display portions of the two display devices have different sizes, the optical system of the electronic device 10 is configured such that images displayed by the two display devices are superimposed on each other when entering the user's eye 20.

As the display device 11a and the display device 11b, it is preferable to use display devices that are equal in one or more of the screen aspect ratio, the kind of the display element, the power supply voltage, and the driving frequency (also referred to as frame frequency). In addition, the pixel circuits of the display device 11a and the display device 11b preferably have the same kind of elements, such as a transistor and a capacitor. In particular, when the display device 11a and the display device 11b are manufactured by the same manufacturer in the same manufacturing line of the same plant, the manufacturing cost of the electronic device 10 can be reduced in some cases.

Using the same kind of the display element, the same transistor structure, and the same capacitor structure for the display device 11a and the display device 11b can reduce a variation in characteristics (e.g., color tone, luminance, color reproducibility, and response speed) between the display device 11a and the display device 11b, which simplifies correction for uniform characteristics as compared with the case of using different kinds of display elements, transistors with different structures, and capacitors with different structures.

Note that as the display device 11a and the display device 11b, display devices in which wirings, terminals, drivers (driver circuits), and the like are all arranged in the same manner or display devices in which one or more of them are arranged in different manners may be used.

The pixel densities of the display device 11a and the display device 11b are preferably as high as possible.

The pixel density of the display device 11a can be, for example, higher than or equal to 1000 ppi and lower than or equal to 20000 ppi, preferably higher than or equal to 2000 ppi and lower than or equal to 15000 ppi, further preferably higher than or equal to 3000 ppi and lower than or equal to 10000, still further preferably higher than or equal to 4000 ppi and lower than or equal to 9000 ppi, yet still further preferably higher than or equal to 5000 ppi and lower than or equal to 8000 ppi.

The pixel density of the display device 11a can be the same as the pixel density of the display device 11b.

Alternatively, the pixel density of the display device 11a can be higher than the pixel density of the display device 11b. For example, the pixel density of the display device 11a can be greater than or equal to 1.5 times, preferably greater than or equal to 1.5 times and less than or equal to 6 times the pixel density of the display device 11b. Specifically, the pixel density of the display device 11a can be twice the pixel density of the display device 11b, for example. Alternatively, for example, the pixel density of the display device 11a can be four times the pixel density of the display device 11b. Note that in the display device 11a, some regions may have higher pixel density than the display device 11b and the other regions may have the same pixel density as the display device 11b.

The pixel density of the display device 11b may be lower than the pixel density of the display device 11a in only one of the horizontal direction (the direction along a row) and the vertical direction (the direction along a column). For example, the pixel density of the display device 11b may be less than or equal to ⅔ times, or greater than or equal to ⅙ and less than or equal to ⅔, specifically, 0.5 times or 0.25 times the pixel density of the display device 11a in the horizontal direction.

The pixel density of the subpixels corresponding to the first color in the display device 11a can be the same as the pixel density of the subpixels corresponding to the second color in the display device 11b. The pixel density of the subpixels corresponding to the first color in the display device 11a can be the same as the pixel density of the subpixels corresponding to the third color in the display device 11b.

Alternatively, the pixel density of the subpixels corresponding to the first color in the display device 11a can be higher than the pixel density of the subpixels corresponding to the second color in the display device 11b. For example, the pixel density of the subpixels corresponding to the first color in the display device 11a can be greater than or equal to 1.5 times, preferably greater than or equal to 1.5 times and less than or equal to 6 times, specifically, for example, 2 times or 4 times the pixel density of the subpixels corresponding to the second color of the display device 11b.

Alternatively, the pixel density of the subpixels corresponding to the first color in the display device 11a can be higher than the pixel density of the subpixels corresponding to the third color in the display device 11b. For example, the pixel density of the subpixels corresponding to the first color in the display device 11a can be greater than or equal to 1.5 times, preferably greater than or equal to 1.5 times and less than or equal to 6 times, specifically, for example, 2 times or 4 times the pixel density of the subpixels corresponding to the third color in the display device 11b.

Larger display portions of the display device 11a and the display device 11b enable the thinner lens 12, and in addition, less image distortion due to the lens. For example, the diagonal size of the display portion of each of the display device 11a and the display device 11b is preferably greater than or equal to 0.3 inches or greater than or equal to 0.5 inches, further preferably greater than or equal to 0.7 inches, still further preferably greater than or equal to 1 inch, yet further preferably greater than or equal to 1.3 inches, and less than or equal to 2 inches or less than or equal to 1.7 inches. Specifically, 1.5 inches or a similar size is preferable.

In the display device 11a and the display device 11b, the diagonal size of the display portion is preferably smaller than the diameter of the lens 12. For example, the diagonal size of the display portion of the display device 11a or the display device 11b is preferably 90% or less, further preferably 80% or less, still further preferably 70% or less of the diameter of the lens 12. Thus, the distortion of an image that can be seen through the lens 12 can be made small, whereby the sense of immersion can be increased. If the diagonal size of the display portion of each of the display device 11a and the display device 11b is larger than the diameter of the lens 12, part of the display portion might be out of the field of view.

Note that the pixel density and the display portion size of the display device 11a and the display device 11b are not limited to the above. For example, in the case where a high definition is not required, a display device having a pixel density lower than 1000 ppi may be used, or a display device having a size greater than 2 inches can be used.

The lens 12 is a lens positioned on the user's eye 20 side and can also be referred to as an eyepiece lens. A convex lens is preferably used as the lens 12.

The half mirror 14 is an optical member having both a reflective property and a transmitting property with respect to visible light. For example, an optical member in which a thin metal film or a dielectric multilayer film is formed on a transparent base such as glass, quartz, resin, or the like can be used. For the half mirror 14, an optical member whose ratio of transmittance to reflectance is 1:1 is preferably used. As long as the half mirror 14 achieves a function of synthesizing two images, another optical member, without limiting to a half mirror, utilizing characteristics such as light reflection, refraction, polarization, diffraction, or scattering can be used. The half mirror 14 has a function of synthesizing two images. Thus, the half mirror 14 is referred to as a combiner in some cases.

In FIG. 1A, tracks of light (an image) emitted by the display device 11a are denoted by dotted lines. The image of the display device 11a is reflected by the half mirror 14 and reaches the user's eye 20 through the lens 12. The user sees an image in such a state that the image displayed on the display device 11a is magnified through the lens 12.

In FIG. 1B, tracks of light emitted by the display device 11b are denoted by dotted lines. The image of the display device 11b passes through the half mirror 14 and reaches the lens 12. The user sees an image in such a state that the image displayed on the display device 11b is magnified through the lens 12.

The image displayed by the display device 11a and the image displayed by the display device 11b are synthesized by the half mirror 14. When the display device 11a and the display device 11b perform display at the same time, the user can see, through the lens 12, an image obtained by superimposing an image from the display device 11a and an image from the display device 11b on each other.

Next, a specific structure of the electronic device 10 is described. FIG. 2A is a schematic view of the electronic device 10. FIG. 2A is a schematic view seen in a direction perpendicular to the optical axis of the lens 12.

In FIG. 2A, the display device 11b is provided on the optical axis of the lens 12. The half mirror 14 is provided at an angle of 45° to the optical axis of the lens 12 and the display device 11a is provided at an angle of 45° to the reflective surface of the half mirror 14. Note that the angle of the half mirror 14 or the like is not limited thereto.

A focal point of the lens 12 on the user's eye 20 side is referred to as a focal point f1a. An example where the user's eye 20 is positioned at the focal point f1a is shown here.

The display device 11a is preferably placed so that the distance of a path from the display surface of the display device 11a to the center of the lens 12 via the reflective surface of the half mirror 14 is shorter than the focal length of the lens 12.

Light (denoted by dashed lines) coming from the display surface of the display device 11a is reflected by the half mirror 14 and reaches the lens 12. The light is condensed by the lens 12 and reaches the user's eye 20. The user sees an image in such a state that the image displayed on the display device 11a is magnified through the lens 12. Here, the image that can be seen by the user's eye 20 is an image inverted horizontally or vertically, by the half mirror 14, from the image displayed on the display portion of the display device 11a. Thus, an image that is inverted horizontally or vertically beforehand is preferably displayed on the display device 11a.

Light (denoted by dashed lines) coming from the display surface of the display device 11b passes through the half mirror 14 and reaches the lens 12. The light is condensed by the lens 12 and reaches the user's eye 20. The user sees an image in such a state that the image displayed on the display device 11b is magnified through the lens 12.

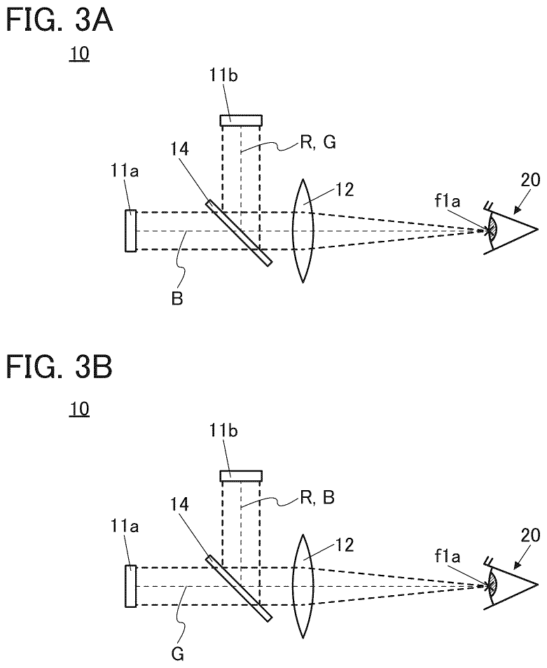

The position of the display device 11a and the position of the display device 11b may be interchanged with each other. FIG. 3A illustrates a structure where the position of the display device 11a and the position of the display device 11b in FIG. 2A are interchanged with each other. FIG. 3B illustrates a structure where the position of the display device 11a and the position of the display device 11b in FIG. 2B are interchanged with each other.

### Structure Example 2

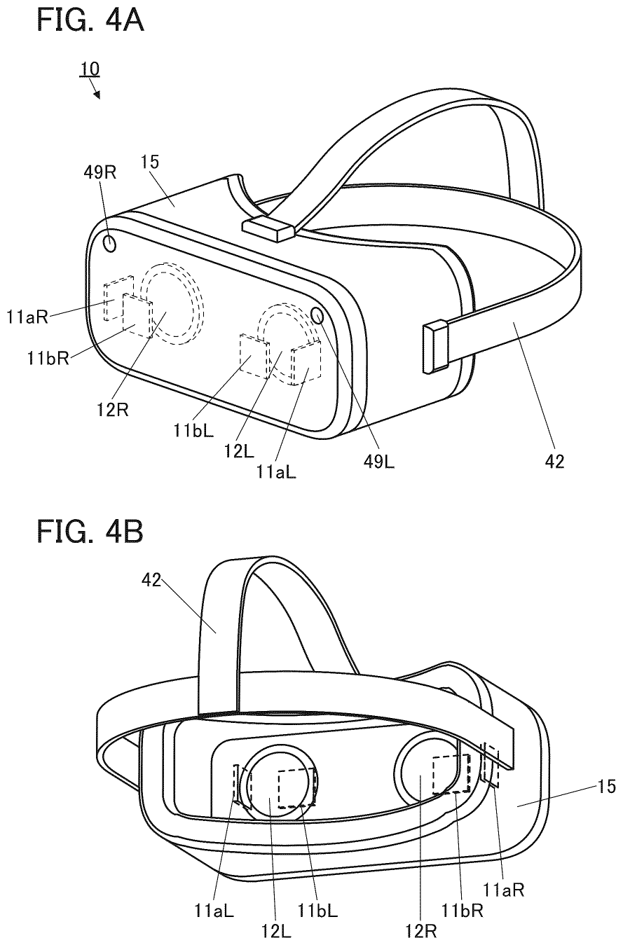

FIG. 4A and FIG. 4B are perspective views of the electronic device 10. The perspective view in FIG. 4A shows the front surface, the top surface, and the left side surface of the electronic device 10, and the perspective view in FIG. 4B illustrates the back surface, the bottom surface, and the right side surface of the electronic device 10. The electronic device 10 is what is called a goggles-type head mounted display (HMD), which can be worn on the head.

The electronic device 10 can be used as an electronic device for VR, for example. The user wearing the electronic device 10 can watch a three-dimensional video using parallax with different videos for the right eye and the left eye.

The electronic device 10 includes a housing 15 and a wearing tool 42. The wearing tool 42 has a function of fixing the housing 15 to the head.

A camera 49R and a camera 49L are provided on the surface of the housing 15. A video taken with the camera 49R and the camera 49L is displayed in real time, whereby the user can know the user's surroundings even when wearing the electronic device 10. Furthermore, a video see-through function can be achieved. A three-dimensional video using parallax can be produced with two or more cameras.

The electronic device 10 includes two lenses 12. The lens 12 for the right eye is referred to as a lens 12R, and the lens 12 for the left eye is referred to as a lens 12L. The electronic device 10 includes two display devices 11a and two display devices 11b. The display device 11a and the display device 11b displaying images for the right eye are referred to as a display device 11aR and a display device 11bR, respectively. The display device 11a and the display device 11b displaying images for the left eye are referred to as a display device 11aL and a display device 11bL, respectively.

On the side of the housing 15 facing the user, the lens 12R functioning as an eyepiece lens for the right eye and the lens 12L functioning as an eyepiece lens for the left eye are provided in portions to be in front of the user's eyes. Furthermore, the display device 11aR and the display device 11bR displaying an image for the right eye and the display device 11aL and the display device 11bL displaying an image for the left eye are provided inside the housing 15. Note that various optical systems given above can be employed; thus, components such as a half mirror and a lens are omitted here.

When the relative position of the display device 11aR and the display device 11bR is shifted, an image is distorted; thus, the display device 11aR and the display device 11bR are preferably fixed to the same frame so that their relative position is not shifted by impact or the like. The same applies to the display device 11aL and the display device 11bL. Meanwhile, the display device 11aR and the display device 11aL are preferably configured to move up and down, forward and backward, and left and right in accordance with the positions of the user's eyes, for example. Thus, the display device 11aR and the display device 11aL may be fixed to separate frames.

An input terminal and an output terminal may be provided on the surface of the housing 15. To the input terminal, a cable for supplying a video signal from a video output device or the like, power for charging a battery provided in the housing 15, or the like can be connected. The output terminal can function as, for example, an audio output terminal to which earphones, headphones, or the like can be connected. Note that in the case where audio data can be output by wireless communication or sound is output from an external video output device, the audio output terminal is not necessarily provided.

A wireless communication module, a memory module, and the like may be provided inside the housing 15. Content to be watched can be downloaded via wireless communication using the wireless communication module and can be stored in the memory module. Accordingly, the user can watch the downloaded content offline whenever the user wants.

At least part of this embodiment can be implemented in appropriate combination with the other embodiments described in this specification.

### Embodiment 2

In this embodiment, structure examples of a display device that can be employed for the electronic device of one embodiment of the present invention will be described. A display device described below as an example can be used as the display device 11a, the display device 11b, and the like in Embodiment 1.

One embodiment of the present invention is a display device including a light-emitting element (also referred to as a light-emitting device). The display device includes two or more light-emitting elements emitting light of different colors. Each pixel includes a light-emitting element. The light-emitting elements each include a pair of electrodes and an EL layer therebetween. The light-emitting elements are preferably organic EL elements (organic electroluminescent elements). Two or more light-emitting elements emitting light of different colors include EL layers containing different light-emitting materials (also referred to as light-emitting substances). For example, when three kinds of light-emitting elements that emit red (R), green (G), and blue (B) light are included, a full-color display device can be achieved.

In the case of manufacturing a display device including a plurality of light-emitting elements emitting light of different colors, layers (light-emitting layers) containing at least light-emitting materials each need to be formed in an island shape. In the case of separately forming part or the whole of an EL layer, a method for forming an island-shaped organic film by an evaporation method using a shadow mask such as a metal mask is known. However, this method causes a deviation from the designed shape and position of the island-shaped organic film due to various influences such as the accuracy of the metal mask, the positional deviation between the metal mask and a substrate, a warp of the metal mask, and expansion of the outline of a formed film due to vapor scattering, for example; accordingly, it is difficult to achieve a high resolution and a high aperture ratio of the display device. In addition, the outline of the layer may blur during vapor deposition, whereby the thickness of an end portion may be reduced. That is, the thickness of the island-shaped light-emitting layer may vary from area to area. In addition, in the case of manufacturing a display device with a large size, a high definition, or a high resolution, a manufacturing yield might be reduced because of low dimensional accuracy of the metal mask and deformation due to heat or the like. Thus, a measure has been taken for a pseudo increase in resolution (also referred to as pixel density) by employing unique pixel arrangement such as PenTile arrangement.

Note that in this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

In one embodiment of the present invention, fine patterning of EL layers is performed by photolithography without using a shadow mask such as a fine metal mask (FMM). Accordingly, it is possible to achieve a display device with a high resolution and a high aperture ratio, which has been difficult to achieve. Moreover, since the EL layers can be formed separately, it is possible to achieve a display device that performs extremely clear display with high contrast and high display quality. Note that, fine patterning of the EL layers may be performed using both a metal mask and photolithography, for example.

In addition, part or the whole of the EL layer can be physically divided. This can inhibit leakage current flowing between adjacent light-emitting elements through a layer (also referred to as a common layer) shared by the light-emitting elements. This can prevent unintended light emission due to crosstalk, so that a display device with extremely high contrast can be achieved. In particular, a display device having high current efficiency at low luminance can be achieved.

Note that a display device of one embodiment of the present invention can also be obtained by combining white-light-emitting elements with a color filter. In that case, light-emitting elements having the same structure can be used as light-emitting elements provided in pixels (subpixels) that emit light of different colors, which allows all the layers to be common layers. In addition, part or the whole of each EL layer is divided by photolithography. Thus, leakage current through the common layer is inhibited; accordingly, a display device with high contrast can be achieved. In particular, when an element has a tandem structure where a plurality of light-emitting layers are stacked with a highly conductive intermediate layer therebetween, leakage current through the intermediate layer can be effectively prevented, so that a display device with high luminance, high resolution, and high contrast can be achieved.

In the case where the EL layer is processed by a photolithography method, part of the light-emitting layer is sometimes exposed to cause deterioration. Thus, an insulating layer covering at least a side surface of the island-shaped light-emitting layer is preferably provided. The insulating layer may cover part of a top surface of an island-shaped EL layer. For the insulating layer, a material having a barrier property against water and oxygen is preferably used. For example, an inorganic insulating film that is less likely to diffuse water or oxygen can be used. This can inhibit deterioration of the EL layer and can achieve a highly reliable display device.

Moreover, between two adjacent light-emitting elements, there is a region (a depressed portion) where none of the EL layers of the light-emitting elements is provided. In the case where a common electrode or a common electrode and a common layer are formed to cover the depressed portion, a phenomenon where the common electrode is divided by a step at an end portion of the EL layer (such a phenomenon is also referred to as disconnection) might occur, which might cause insulation of the common electrode over the EL layer. In view of this, a local gap between the two adjacent light-emitting elements is preferably filled with a resin layer functioning as a planarization film (such a structure is also referred to as local filling planarization, or LFP). The resin layer has a function of a planarization film. This structure can inhibit disconnection of the common layer or the common electrode and can achieve a highly reliable display device.

More specific structure examples of the display device of one embodiment of the present invention will be described below with reference to drawings.

### Structure Example 1

The subpixel included in the display device can have any of a variety of top surface shapes such as a polygonal shape, an elliptical shape, and a circular shape. Furthermore, the top surface shape of the subpixel included in the display device may have a rounded corner. The top surface shape of the subpixel illustrated in a diagram in this embodiment corresponds to the top surface shape of a light-emitting region, for example.

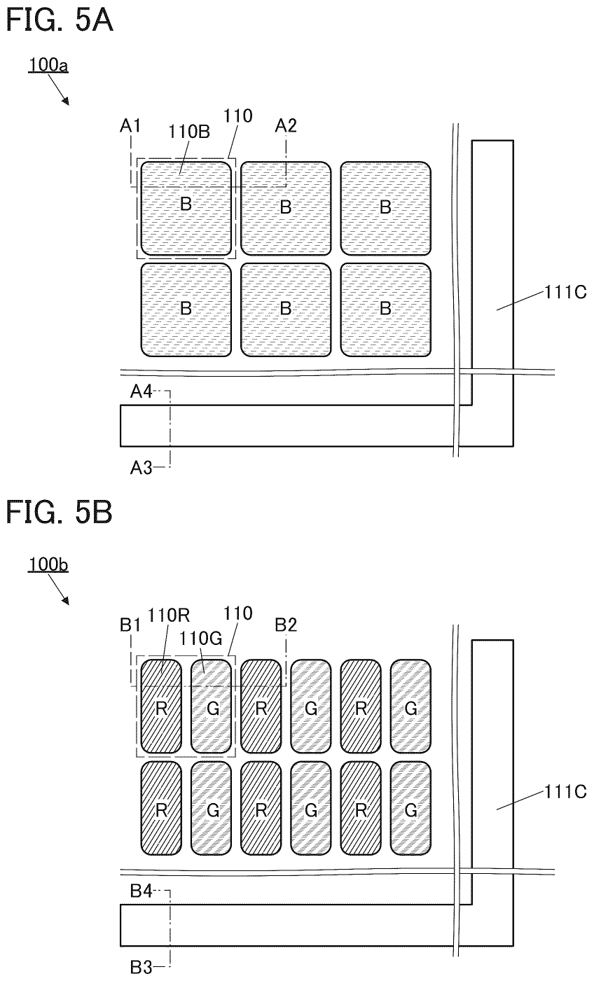

FIG. 5A is a schematic top view of a display device 100a of one embodiment of the present invention. The display device 100a is a display device performing monochromatic display, in which light-emitting elements exhibiting a first color are arranged in a matrix over a substrate. FIG. 5A illustrates an example where the display device 100a includes a plurality of pixels 110 over the substrate and the pixel 110 includes a light-emitting element 110B (a subpixel 110B) exhibiting blue.

FIG. 5B is a schematic top view of a display device 100b of one embodiment of the present invention. The display device 100b includes light-emitting elements exhibiting a second color and light-emitting elements exhibiting a third color over a substrate. The light-emitting elements exhibiting the second color and the light-emitting elements exhibiting the third color are each arranged in a matrix. Although not illustrated in FIG. 5B, the display device 100b may include a light-emitting element exhibiting a fourth color. In the example illustrated in FIG. 5B, the display device 100b includes a plurality of pixels 110 over the substrate, and the pixel 110 includes a light-emitting element 110R (a subpixel 110R) exhibiting red and a light-emitting element 110G (a subpixel 110G) exhibiting green. The electronic device of one embodiment of the present invention displays an image, for example, in a state where the subpixel 110R and the subpixel 110G included in the display device 100b overlap with the subpixel 110B included in the display device 100a. Thus, the electronic device displays the image, for example, in a state where the pixel 110 illustrated in FIG. 5A and the pixel 110 illustrated in FIG. 5B overlap with each other.

In FIG. 5A and FIG. 5B, light-emitting regions of the light-emitting elements are denoted by R, G, and B to easily differentiate the light-emitting elements. FIG. 5A and FIG. 5B illustrate an example where the display device 100a includes a plurality of light-emitting elements emitting blue light and the display device 100b includes a plurality of light-emitting elements emitting red light and a plurality of light-emitting elements emitting green light; however, the combination of the color of the light-emitting elements included in the display device 100a and the colors of the light-emitting elements included in the display device 100b is not limited thereto. For example, the display device 100a may include a plurality of light-emitting elements emitting green light, and the display device 100b may include a plurality of light-emitting elements emitting red light and a plurality of light-emitting elements emitting blue light.

The display device 100a can be appropriately used as the display device 11a and the display device 11b described in the above embodiment. The display device 100b can be appropriately used as the display device 11a and the display device 11b described in the above embodiment. For example, the display device 100a may be used as one of the display device 11a and the display device 11b that performs monochromatic display, and the display device 100b may be used as the other of the display device 11a and the display device 11b that does not employ the display device 100a.

FIG. 5(B) illustrates what is called stripe arrangement, in which the light-emitting elements of the same color are arranged in one direction. Note that an arrangement method of the light-emitting elements is not limited thereto; an arrangement method such as S-stripe arrangement, delta arrangement, Bayer arrangement, or zigzag arrangement may be employed, or PenTile arrangement, diamond arrangement, or the like can also be used.

As each of the light-emitting elements 110R, the light-emitting elements 110G, and the light-emitting elements 110B, an OLED (Organic Light Emitting Diode) or a QLED (Quantum-dot Light Emitting Diode) is preferably used, for example. As examples of a light-emitting substance contained in the light-emitting element, a substance that emits fluorescent light (a fluorescent material), a substance that emits phosphorescent light (a phosphorescent material), and a substance that exhibits thermally activated delayed fluorescence (a thermally activated delayed fluorescent (TADF) material) can be given. As the light-emitting substance contained in the light-emitting element, not only an organic compound but also an inorganic compound (a quantum dot material or the like) can be used.

FIG. 5A and FIG. 5B also illustrate a connection electrode 111C that is electrically connected to a common electrode (a common electrode 113 to be described later) of the light-emitting elements. The connection electrode 111C is supplied with a potential (e.g., an anode potential or a cathode potential) that is to be supplied to the common electrode 113. The connection electrode 111C is provided outside a display region where the light-emitting elements 110R and the like are arranged. The connection electrodes 111C are denoted by the same reference numeral in the display device 100a and the display device 100b; however, the connection electrodes 111C in the display devices are not a continuous film, although they have similar materials, similar properties, or the like.

The connection electrode 111C can be provided along the outer periphery of the display region. For example, the connection electrode 111C may be provided along one side of the outer periphery of the display region, or may be provided along two or more sides of the outer periphery of the display region. That is, in the case where the display region has a rectangular top surface shape, the top surface shape of the connection electrode 111C can be a band shape (a rectangle), an L shape, a U shape (a square bracket shape), a quadrangular shape, or the like.

Note that the display device 100a is a display device that performs monochromatic display and does not necessarily include subpixels corresponding to different colors in one pixel; thus, the area of the subpixel can be increased and the light-emitting area of the light-emitting element can be increased. The subpixel 110B illustrated in FIG. 5A can have a structure with a larger width than the subpixel 110R and the subpixel 110G, for example. Thus, the subpixel 110B has an area twice or more larger than those of the subpixel 110R and the subpixel 110G illustrated in FIG. 5B. In the display device 100a and the display device 100b in FIG. 5A and FIG. 5B, the area of the pixel 110 is substantially the same. Note that FIG. 5A and FIG. 5B are illustrated with substantially the same scale.

In a plan view, the width and the length of the pixel included in the display device are preferably substantially the same. When the width and the length are substantially the same, the resolution in the horizontal direction and the resolution in the vertical direction of the display device can be substantially the same, leading to higher display quality.

FIG. 5A illustrates an example where the top surface shape of the subpixel included in the display device 100a is substantially square. Note that although the top surface shape of the subpixel in FIG. 5A is not limited to a square, the width and the length of the top surface shape of the subpixel are preferably substantially the same.

In FIG. 5A, the area of the subpixel 110B corresponding to blue light emission can be increased. Thus, the light-emitting area of the light-emitting element included in the subpixel 110B can be increased. This can reduce the luminance per area of the light-emitting element corresponding to blue light emission, thereby extending the lifetime of the display element and the display device 100a.

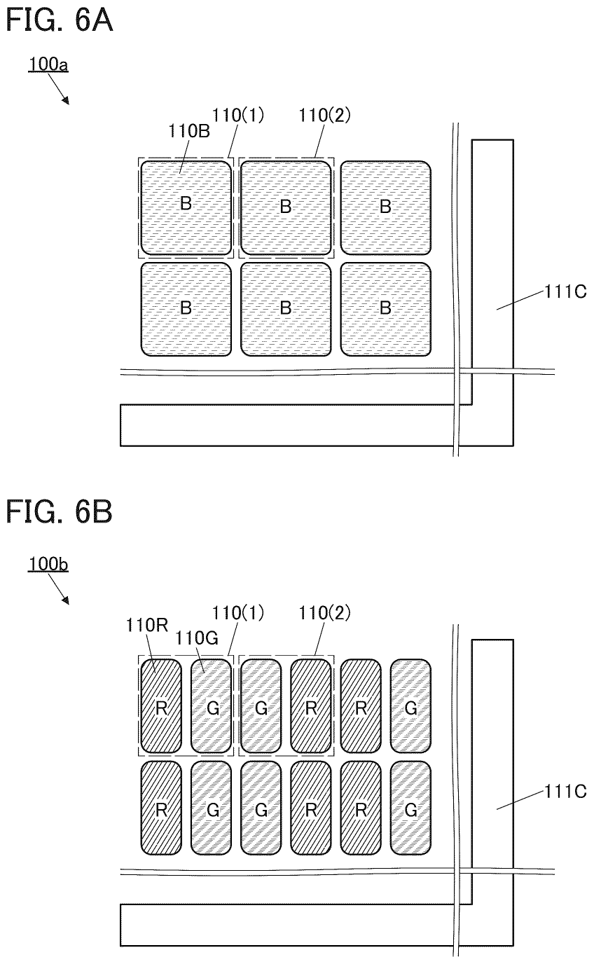

FIG. 6B illustrates an example where the subpixels 110R and the subpixels 110G in the display device 100b are arranged in a manner different from that of FIG. 5B. The display device 100b illustrated in FIG. 6B has a structure where two subpixels displaying the same color are adjacent to each other in the horizontal direction. For example, an organic layer 112 (here, an organic layer 112R or an organic layer 112G) can be continuous in adjacent subpixels of the same color, which eliminates the need for processing the organic layer 112 into an island shape for each subpixel. This can increase the processing size of the organic layer 112, leading to easy fabrication of the display device 100b.

Note that the display device 100a and the display device 100b each include two pixels 110 (hereinafter, a pixel 110(1) and a pixel 110(2)) that differ in subpixel arrangement. In the display device 100b, the pixel 110(1) and the pixel 110(2) have horizontally inverted structures.

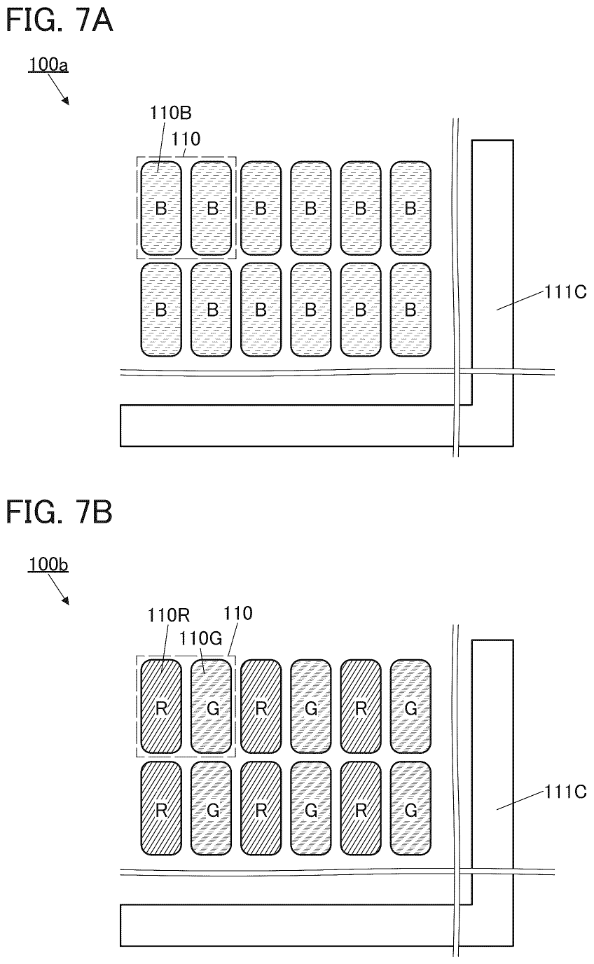

FIG. 7A and FIG. 7B illustrate an example where the subpixels 110R, 110G, and 110B have substantially the same area. In the example illustrated in FIG. 7A and FIG. 7B, the display device 100a includes two subpixels 110B arranged side by side in the pixel 110. In FIG. 7A and FIG. 7B, two subpixels 110B included in the pixel 110 may be supplied with the same image signal, for example. Alternatively, two subpixels 110B included in the pixel 110 may be supplied with different signals so that the resolution in the horizontal direction is higher in the display device 100a than in the display device 100b.

Note that in FIG. 5A, FIG. 5B, FIG. 6A, FIG. 6B, FIG. 7A, and FIG. 7B, the color displayed by the subpixels included in the display device 100a and the colors displayed by the subpixels included in the display device 100b are not limited to the above. For example, the subpixel 110G may be used instead of the subpixel 110B included in the display device 100a, and the subpixel 110B may be used instead of the subpixel 110G included in the display device 100b.

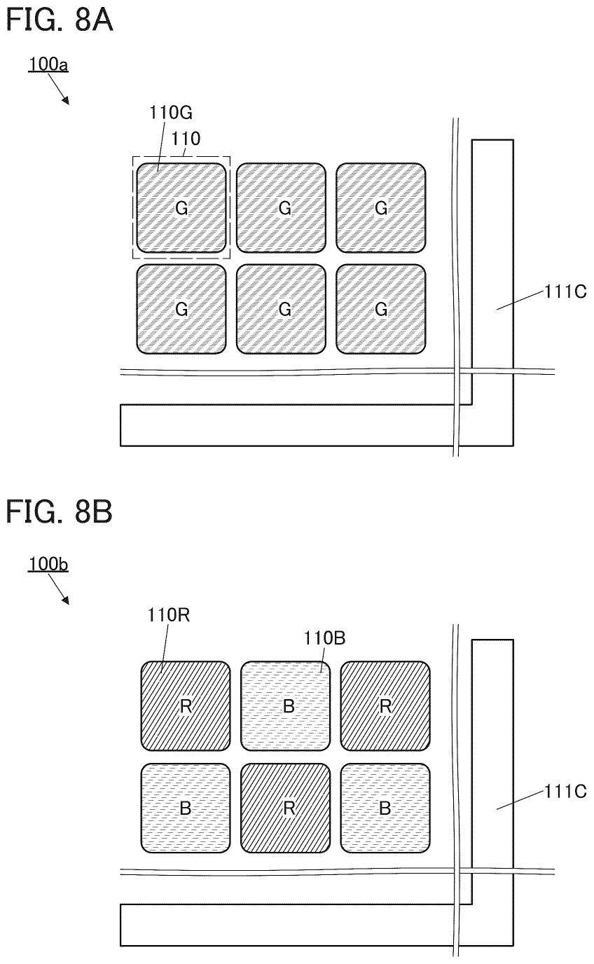

FIG. 8A and FIG. 8B illustrate an example where the display device 100a includes the subpixel 110G and the display device 100b includes the subpixel 110R and the subpixel 110B. Note that in FIG. 8A and FIG. 8B, the area of one subpixel is substantially square. Green has a high luminosity factor. When the pixel pitch of the display device 100a is decreased, the resolution of a color with a high luminosity factor can be increased in the display portion. Increasing the resolution of the color with a high luminosity factor allows a user observing an image displayed by the electronic device 10 to feel that the resolution of the image is high.

FIG. 8B illustrates an example where the subpixels 110R and the subpixels 110B included in the display device 100b are arranged in a lattice pattern. That is, in the display device 100b, the subpixels 110R and the subpixels 110B are alternately arranged in the row direction and the column direction. Note that the arrangement of the subpixels 110R and the subpixels 110B illustrated in FIG. 8B is referred to as staggered arrangement in some cases.

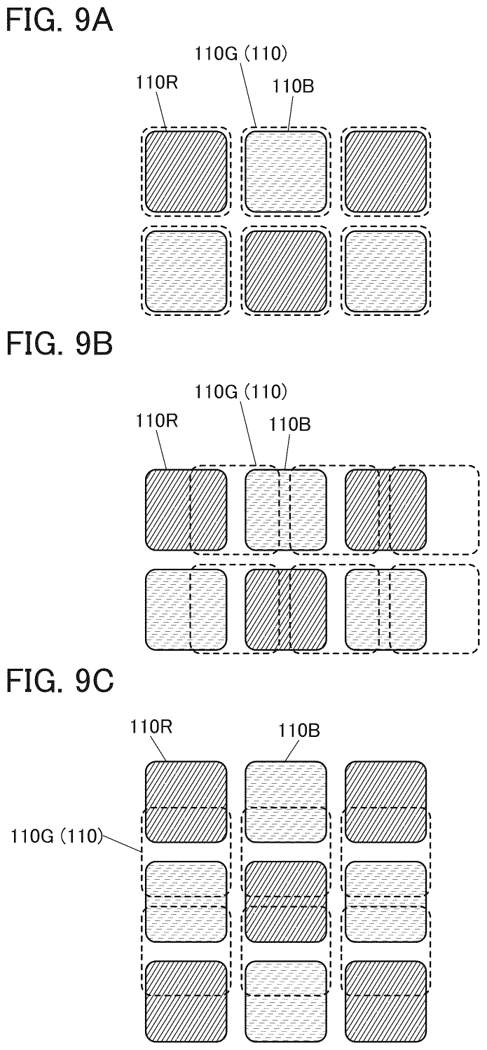

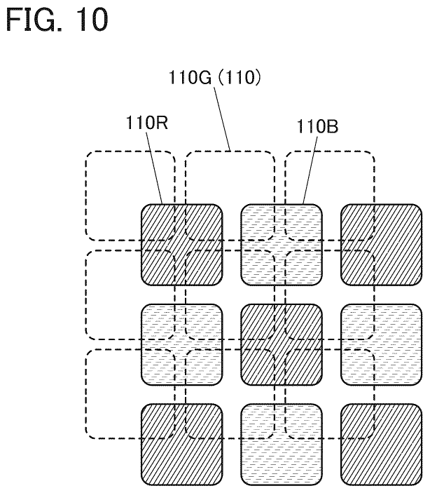

In FIG. 8A, the pixel 110 of the display device 100a includes one subpixel 110G. In the case where the display device 100a in FIG. 8A overlaps with the display device 100b in FIG. 8B, which region of the display device 100b corresponds to the pixel 110 changes depending on how the pixel 110 of the display device 100b overlaps with the pixel 110 of the display device 100a. FIG. 9A, FIG. 9B, FIG. 9C, and FIG. 10 illustrate variations of overlap of the pixel 110 of the display device 100a in FIG. 8A and the subpixels of the display device 100b in FIG. 8B.

First, in FIG. 9A, FIG. 9B, FIG. 9C, and FIG. 10, the subpixel 110G of the display device 100a corresponds to the pixel 110. In FIG. 9A, FIG. 9B, FIG. 9C, and FIG. 10, the subpixel of the display device 100a (here, the subpixel 110G) overlaps with the subpixels of the display device 100b (here, the subpixel 110R and the subpixel 110B) in an image formed by synthesizing an image displayed by the display device 100a and an image displayed by the display device 100b. Note that in FIG. 9A, FIG. 9B, FIG. 9C, and FIG. 10, the area of the subpixel 110G is illustrated to be larger than the area of each of the subpixel 110R and the subpixel 110B for easy viewing of the overlap of the subpixels; however, the areas of the subpixel 110G, the subpixel 110R, and the subpixel 110B may be substantially the same or different from each other.

FIG. 9A illustrates an example where the subpixel 110G of the display device 100a and the subpixel 110R or the subpixel 110B of the display device 100b overlap with each other.

FIG. 9B illustrates an example where approximately half areas of the subpixel 110G of the display device 100a overlap with the subpixel 110R and the subpixel 110B of the display device 100b. In FIG. 9B, the subpixel 110G overlaps with the subpixel 110R and the subpixel 110B that are horizontally adjacent to each other in a top view. In the example illustrated in FIG. 9B, each of the subpixels 110G of the display device 100a overlaps with both the subpixel 110R and the subpixel 110B of the display device 100b in the synthesized image, which brings advantage that a natural image can be easily obtained.

The structure where each of the subpixels 110G of the display device 100a overlaps with both the subpixel 110R and the subpixel 110B of the display device 100b is not limited to that in FIG. 9B, and can be structures illustrated in FIG. 9C and FIG. 10.

FIG. 9C illustrates an example where the subpixel 110G overlaps with the subpixel 110R and the subpixel 110B that are adjacent to each other in the vertical direction in a top view.

In FIG. 10, one of the subpixels of the display device 100a is placed to overlap with four subpixels arranged in two rows and two columns in the display device 100b. Alternatively, it can be expressed that one of the subpixels of the display device 100b is placed to overlap with four subpixels arranged in two rows and two columns in the display device 100a.

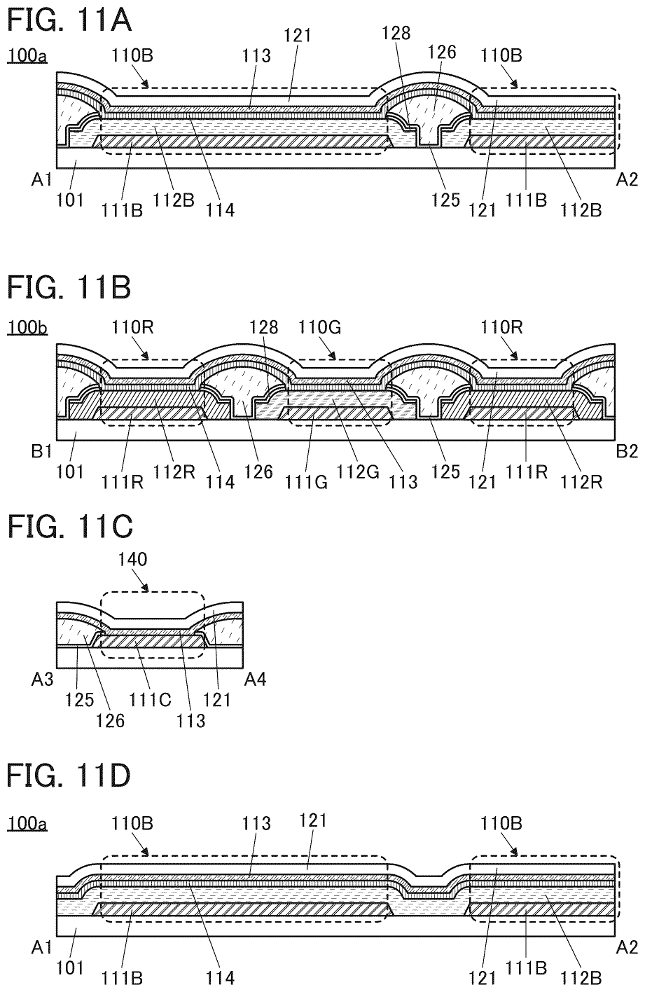

FIG. 11A is a schematic cross-sectional view taken along dashed-dotted line A1-A2 in FIG. 5A. FIG. 11B is a schematic cross-sectional view taken along dashed-dotted line B1-B2 in FIG. 5B. FIG. 11C is a schematic cross-sectional view applicable to both the dashed-dotted line A3-A4 in FIG. 5A and the dashed-dotted line B3-B4 in FIG. 5B. FIG. 11A is the schematic cross-sectional view of the light-emitting element 110B, FIG. 11B is the schematic cross-sectional view of the light-emitting element 110R and the light-emitting element 110G, and FIG. 11C is the schematic cross-sectional view of a connection portion 140 where the connection electrode 111C and the common electrode 113 are connected to each other.

The display device 100a illustrated in FIG. 11A includes the light-emitting element 110B over a layer 101. The light-emitting element 110B includes a pixel electrode 111B, an organic layer 112B, a common layer 114, and the common electrode 113. The display device 100b illustrated in FIG. 11B includes the light-emitting element 110R and the light-emitting element 110G over the layer 101. The light-emitting element 110R includes a pixel electrode 111R, the organic layer 112R, the common layer 114, and the common electrode 113. The light-emitting element 110G includes a pixel electrode 111G, the organic layer 112G, the common layer 114, and the common electrode 113. In FIG. 11B, the common layer 114 and the common electrode 113 are provided to be shared by the light-emitting element 110R and the light-emitting element 110G.

Components such as the common layer 114 and the common electrode 113 are each denoted by the same reference numeral in the display device 100a and the display device 100b; however, the components with the same reference numerals are not a continuous film although they have similar materials, similar properties, or the like.

Note that FIG. 11A illustrates an example where the organic layer 112B included in the light-emitting element 110B is formed into an island shape for each light-emitting element; however, as illustrated in FIG. 11D, the organic layer 112B may be provided across a plurality of light-emitting elements 110B without being formed into an island shape.

The organic layer 112B included in the light-emitting element 110B contains at least a light-emitting organic compound that emits blue light. The organic layer 112R included in the light-emitting element 110R contains at least a light-emitting organic compound that emits red light. The organic layer 112G included in the light-emitting element 110G contains at least a light-emitting organic compound that emits green light. Each of the organic layer 112B, the organic layer 112R, and the organic layer 112G can be also referred to as an EL layer and includes at least a layer containing a light-emitting organic compound (a light-emitting layer).

Hereinafter, in description common to the organic layer 112B, the organic layer 112R, and the organic layer 112G, the term “organic layer 112” is used for the description in some cases. Similarly, in description common to the components that are distinguished by alphabets, such as the pixel electrode 111B, the pixel electrode 111R, and the pixel electrode 111G, the reference numeral without an alphabet is sometimes used.

As the layer 101, any of a variety of substrates can be used, for example.

A semiconductor substrate can be used as the substrate. Specifically, as the substrate, a single crystal semiconductor substrate or a polycrystalline semiconductor substrate using silicon, silicon carbide, or the like as a material, a compound semiconductor substrate of silicon germanium or the like, an SOI substrate, or the like can be used. Alternatively, an insulating substrate such as a glass substrate, a quartz substrate, a sapphire substrate, or a plastic substrate may be used as the substrate. The substrate may have flexibility.

A circuit substrate including a transistor, a wiring, or the like is preferably used for the layer 101. For example, a substrate provided with a circuit for driving the light-emitting elements (also referred to as a pixel circuit) or a semiconductor circuit functioning as a driver circuit for driving the pixel circuit can be used for the layer 101.

For the layer 101, it is particularly preferable to use the semiconductor substrate or the insulating substrate where a semiconductor circuit including a semiconductor element such as a transistor is formed. The semiconductor circuit preferably forms a pixel circuit, a gate line driver circuit (gate driver), a source line driver circuit (source driver), or the like. In addition to the above, an arithmetic circuit, a memory circuit, or the like may be formed.

Each of the organic layer 112 and the common layer 114 can independently include one or more of an electron-injection layer, an electron-transport layer, a hole-injection layer, and a hole-transport layer. For example, it is possible to employ a structure where the organic layer 112 includes a stacked-layer structure of a hole-injection layer, a hole-transport layer, a light-emitting layer, and an electron-transport layer from the pixel electrode 111 side and the common layer 114 includes an electron-injection layer.

The pixel electrode 111B, the pixel electrode 111R, and the pixel electrode 111G are provided for the respective light-emitting elements. In addition, the common electrode 113 and the common layer 114 are each provided as a continuous layer shared by the light-emitting elements. A conductive film having a property of transmitting visible light is used for either the pixel electrodes or the common electrode 113, and a conductive film having a reflective property is used for the other. When the pixel electrodes have a light-transmitting property and the common electrode 113 has a reflective property, a bottom-emission display device can be obtained. In contrast, when the pixel electrodes have a reflective property and the common electrode 113 has a light-transmitting property, a top-emission display device can be obtained. Note that when both the pixel electrodes and the common electrode 113 have a light-transmitting property, a dual-emission display device can be also obtained.

In FIG. 11A and FIG. 11D, a protective layer 121 is provided over the common electrode 113 to cover the light-emitting element 110B. In FIG. 11B, the protective layer 121 is provided to cover the light-emitting element 110R and the light-emitting element 110G. The protective layer 121 has a function of preventing diffusion of impurities such as water into each light-emitting element from the above.

An end portion of the pixel electrode 111 preferably has a tapered shape. In the case where the end portion of the pixel electrode 111 has a tapered shape, the organic layer 112 provided along the end portion of the pixel electrode 111 can have a shape with an inclined portion. When the end portion of the pixel electrode 111 has a tapered shape, coverage with the organic layer 112 provided beyond the end portion of the pixel electrode 111 can be increased. Furthermore, when the side surface of the pixel electrode 111 has a tapered shape, a material (for example, also referred to as dust or particles) in a manufacturing step is easily removed by processing such as cleaning, which is preferable.

Note that in this specification and the like, a tapered shape refers to a shape such that at least part of a side surface of a component is inclined to a substrate surface. For example, a tapered shape preferably includes a region where the angle between the inclined side surface and the substrate surface (such an angle is also referred to as a taper angle) is less than 90°.

The organic layer 112 is processed into an island shape by a photolithography method. Thus, an angle formed by the top and side surfaces of the end portion of the organic layer 112 is approximately 90°. By contrast, an organic film formed using an FMM or the like has a thickness that tends to gradually decrease with decreasing distance to the end portion, and the top surface has a slope shape in the range of greater than or equal to 1 μm and less than or equal to 10 μm, for example; thus, such an organic film has a shape whose top and side surfaces cannot be easily distinguished from each other.

An insulating layer 125, a resin layer 126, and a layer 128 are included between two adjacent light-emitting elements.

Between two adjacent light-emitting elements, the side surfaces of the organic layers 112 are provided to face each other with the resin layer 126 therebetween. The resin layer 126 is positioned between the two adjacent light-emitting elements and is provided to fill a region between the two organic layers 112. In FIG. 11A and FIG. 11B, the resin layer 126 is provided to cover end portions of the organic layers 112. The resin layer 126 has a top surface with a smooth convex shape, and the common layer 114 and the common electrode 113 are provided to cover the top surface of the resin layer 126.

The resin layer 126 functions as a planarization film that fills a gap positioned between two adjacent light-emitting elements. Providing the resin layer 126 can prevent a phenomenon in which the common electrode 113 is divided by a step at an end portion of the organic layer 112 (such a phenomenon is also referred to as disconnection) from occurring and the common electrode over the organic layer 112 from being insulated. The resin layer 126 can be also referred to as LFP (Local Filling Planarization).

An insulating layer containing an organic material can be suitably used as the resin layer 126. For the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of these resins, or the like can be used, for example. For the resin layer 126, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Alternatively, a photosensitive resin can be used for the resin layer 126. A photoresist may be used for the photosensitive resin. As the photosensitive resin, a positive material or a negative material can be used.

The resin layer 126 may contain a material absorbing visible light. For example, the resin layer 126 itself may be made of a material absorbing visible light, or the resin layer 126 may contain a pigment absorbing visible light. For example, for the resin layer 126, it is possible to use a resin that can be used as a color filter transmitting red, blue, or green light and absorbing other light, a resin that contains carbon black as a pigment and functions as a black matrix, or the like.

The insulating layer 125 is provided in contact with the side surface of the organic layer 112. In addition, the insulating layer 125 is provided to cover an upper end portion of the organic layer 112. Furthermore, part of the insulating layer 125 is provided in contact with the top surface of the layer 101.

The insulating layer 125 is positioned between the resin layer 126 and the organic layer 112 and functions as a protective film for preventing contact between the resin layer 126 and the organic layer 112. When the organic layer 112 and the resin layer 126 are in contact with each other, the organic layer 112 might be dissolved in an organic solvent or the like used at the time of forming the resin layer 126. Therefore, the insulating layer 125 is provided between the organic layer 112 and the resin layer 126 to protect the side surfaces of the organic layer 112.

An insulating layer containing an inorganic material can be used as the insulating layer 125. For the insulating layer 125, an inorganic insulating film such as an oxide insulating film, a nitride insulating film, an oxynitride insulating film, or a nitride oxide insulating film can be used, for example. The insulating layer 125 may have either a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD method is employed for the insulating layer 125, it is possible to form the insulating layer 125 that has a small number of pinholes and has an excellent function of protecting the EL layer.

Note that in this specification and the like, oxynitride refers to a material that contains more oxygen than nitrogen in its composition, and nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

For the formation of the insulating layer 125, a sputtering method, a CVD method, a PLD method, an ALD method, or the like can be used. The insulating layer 125 is preferably formed by an ALD method that provides good coverage.

In addition, a structure may be employed where a reflective film (e.g., a metal film containing one or more selected from silver, palladium, copper, titanium, aluminum, and the like) is provided between the insulating layer 125 and the resin layer 126 so that light emitted from the light-emitting layer is reflected by the reflective film. This can improve light extraction efficiency.

The layer 128 is a remaining part of a protective layer (also referred to as a mask layer or a sacrificial layer) for protecting the organic layer 112 during etching of the organic layer 112. For the layer 128, a material that can be used for the insulating layer 125 can be used. It is particularly preferable to use the same material for the layer 128 and the insulating layer 125 because an apparatus or the like for processing can be used in common.

In particular, since a metal oxide film such as an aluminum oxide film or a hafnium oxide film or an inorganic insulating film such as a silicon oxide film that is formed by an ALD method has a small number of pinholes, such a film has an excellent function of protecting the EL layer and can be suitably used for the insulating layer 125 and the layer 128.

The protective layer 121 can have, for example, a single-layer structure or a stacked-layer structure including at least an inorganic insulating film. Examples of the inorganic insulating film include an oxide film and a nitride film, such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as an indium gallium oxide, an indium zinc oxide, an indium tin oxide, or an indium gallium zinc oxide may be used for the protective layer 121.

For the protective layer 121, a stacked film of an inorganic insulating film and an organic insulating film can also be used. For example, a structure where an organic insulating film is interposed between a pair of inorganic insulating films is preferable. Furthermore, the organic insulating film preferably functions as a planarization film. This enables the top surface of the organic insulating film to be flat, which results in improved coverage with the inorganic insulating film thereover and a higher barrier property. Moreover, the top surface of the protective layer 121 is flat, which is preferable because the influence of an uneven shape due to a lower structure can be reduced in the case where a component (e.g., a color filter, an electrode of a touch sensor, a lens array, or the like) is provided above the protective layer 121.

FIG. 11C illustrates the connection portion 140 in which the connection electrode 111C and the common electrode 113 are electrically connected to each other. In the connection portion 140, an opening portion is provided in the insulating layer 125 and the resin layer 126 over the connection electrode 111C. The connection electrode 111C and the common electrode 113 are electrically connected to each other in the opening portion.

Note that although FIG. 11C illustrates the connection portion 140 in which the connection electrode 111C and the common electrode 113 are electrically connected to each other, the common electrode 113 may be provided over the connection electrode 111C with the common layer 114 therebetween. Particularly in the case where a carrier-injection layer is used as the common layer 114, for example, a material used for the common layer 114 has sufficiently low electrical resistivity and the common layer 114 can be formed to be thin. Thus, problems do not arise in many cases even when the common layer 114 is positioned in the connection portion 140. Accordingly, the common electrode 113 and the common layer 114 can be formed using the same shielding mask, so that manufacturing cost can be reduced.

At least part of this embodiment can be implemented in appropriate combination with the other embodiments described in this specification.

### Embodiment 3

In this embodiment, examples of electronic devices of embodiments of the present invention will be described.

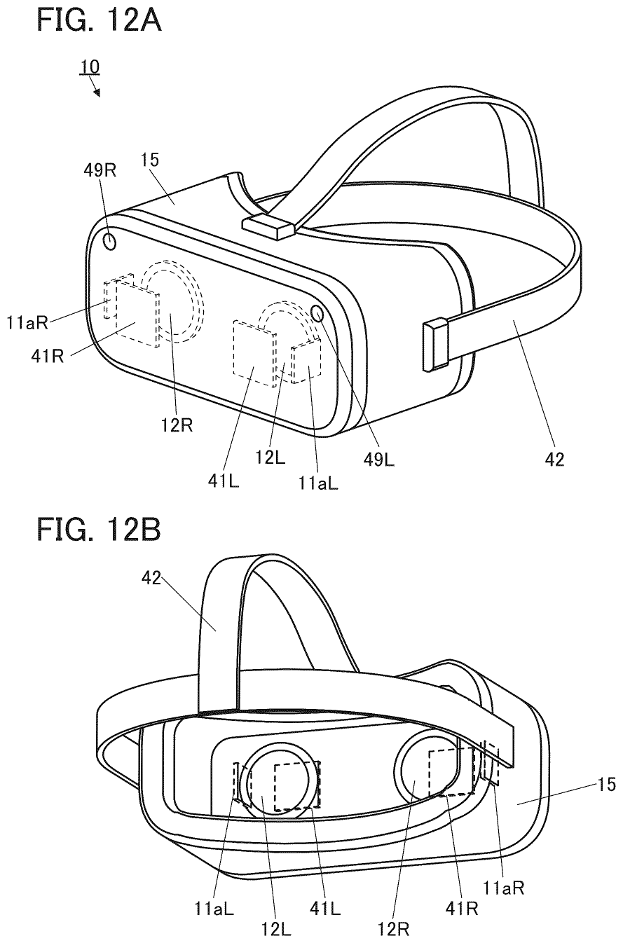

FIG. 12A and FIG. 12B illustrate an example where a display device 41 is used instead of the display device 11b in the electronic device 10 illustrated in FIG. 4A and FIG. 4B.

In the electronic device 10, the display device 41 can be used instead of the display device 11a or the display device 11b. The display device 41 can be used instead of the display device 11b illustrated in FIG. 2A, FIG. 2B, and FIG. 4 or the display device 11a illustrated in FIG. 3A and FIG. 3B, for example. The display device 41 displaying images for the right eye is referred to as a display device 41R, and the display device 41 displaying images for the left eye is referred to as a display device 41L.

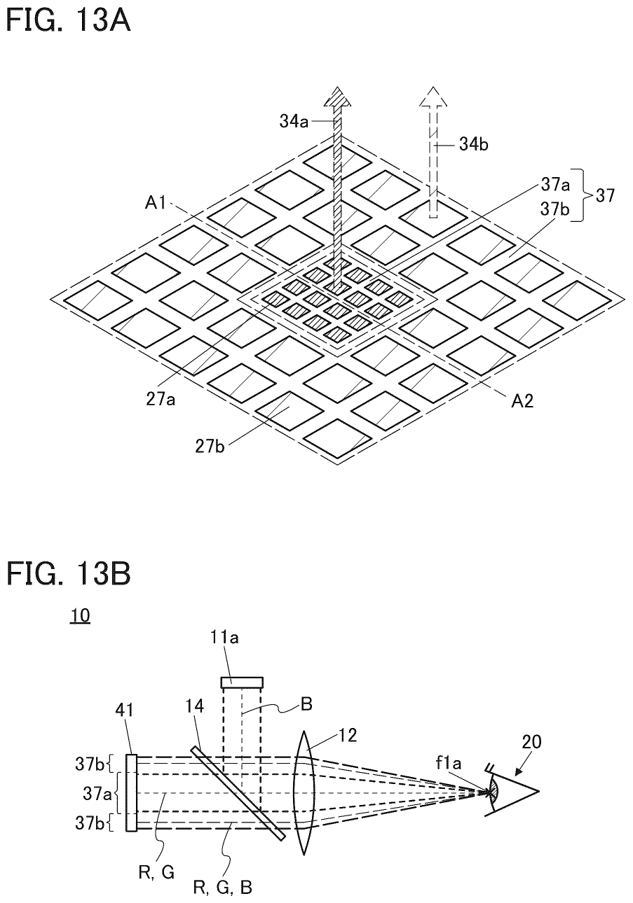

The display device 41 includes a display portion 37 and a driver circuit. A structure example of the display portion 37 that can be employed for the display device 41 is described with reference to FIG. 13A. The display portion 37 includes a display portion 37a with a high pixel density and a display portion 37b with a lower pixel density than the display portion 37a. The display portion 37b can be a region around the display portion 37a. The display device 41R and the display device 41L each include the display portion 37a and the display portion 37b. The pixel density of the display portion 37b can be lower than 1000 ppi, preferably higher than or equal to 50 ppi and lower than 1000 ppi, further preferably higher than or equal to 100 ppi and lower than or equal to 800 ppi.

FIG. 13A is a plan view illustrating the structure example of the display portion 37.

The display portion 37 includes the display portion 37a and the display portion 37b. The display portion 37a can be a region in the center and its vicinity of the display portion 37, and the display portion 37b can be a region around the display portion 37a. That is, the display portion 37b is provided to surround the display portion 37a in a plan view. Accordingly, the user of the electronic device 10 can see an image displayed on the display portion 37a at the center of the visual field and its vicinity and can see an image displayed on the display portion 37b at the peripheral visual field.

The display portion 37 can also be expressed as having a structure where a low-resolution display portion is added to the vicinity of the display portion of the display device 11a or the display portion of the display device 11b included in the electronic device 10.

Note that the center of the display portion 37 may be positioned not in the display portion 37a but in the display portion 37b. The display portion 37b does not necessarily surround the display portion 37a entirely. For example, in the case where the shape of the display portion 37a is a rectangular shape, the display portion 37b does not necessarily surround all of the four sides of the display portion 37a. For example, the display portion 37b can surround three of the four sides of the display portion 37a. Alternatively, the display portion 37b may surround two of the four sides of the display portion 37a entirely and surround the other two sides partially.

A pixel 27a and a pixel 27b are provided with a pixel circuit having a function of controlling the driving of the light-emitting element. The pixel circuit includes a transistor. Thus, the display portion 37a and the display portion 37b can be driven by an active matrix method.

As illustrated in FIG. 13A, the pixel density of the display portion 37a is higher than the pixel density of the display portion 37b. For example, the area occupied by each of the pixels 27a provided in the display portion 37a is smaller than the area occupied by each of the pixels 27b provided in the display portion 37b. The distance between the pixels 27a is shorter than the distance between the pixels 27b. As described above, the display portion 37a can display an image seen at the center of the visual field of the user of the electronic device 10 and its vicinity, and the display portion 37b can display an image seen in the peripheral visual field. Here, a human recognizes an image at the center of the visual field and its vicinity minutely and recognizes an image outside the vicinity more roughly. For example, a human recognizes an image in the central visual field and the effective visual field minutely and recognizes an image in the peripheral visual field more roughly. Thus, the user of the electronic device 10 rarely perceives a decrease in the display quality, e.g., rarely perceives graininess, even when the pixel density of the display portion 37b is lower than the pixel density of the display portion 37a and the resolution of an image displayed on the display portion 37b is lower than the resolution of an image displayed on the display portion 37a. On the other hand, when the pixel density of the display portion 37b is low, the area occupied by the whole display portion 37 can be increased, for example. Accordingly, when the pixel density of the display portion 37b is lower than the pixel density of the display portion 37a, the area occupied by the display portion 37 can be increased without making the user of the electronic device perceive a decrease in the display quality as compared with the case where the whole display portion 37 has uniform pixel density.

The display device 41 can be used instead of the display device 11b in the electronic device 10 illustrated in FIG. 2A and FIG. 2B, for example. In that case, for example, full-color display can be achieved by superimposing an image displayed by the display portion 37a of the display device 41 and an image displayed by the display portion of the display device 11a.

As an example, FIG. 13B illustrates an example where the display device 41 is used instead of the display device 11b in the electronic device 10 illustrated in FIG. 2A. In FIG. 13B, an image displayed by the display device 11a and an image displayed by the display portion 37a of the display device 41 are superimposed on each other and viewed by the user through the lens 12. In FIG. 11B, an image displayed by the display portion 37b of the display device 41 is viewed by the user through the lens 12 as an image of a peripheral region of an image displayed by the display device 11a and an image displayed by the display portion 37a. Note that in the image viewed by the user through the lens 12, an image displayed by the display portion 37b and an image displayed by the display device 11a are preferably not superimposed on each other. Note that an image displayed by the display device 11a and an image displayed by the display portion 37b may be superimposed on each other around the vicinity of an image displayed by the display device 11a.

The display device 41 can be used instead of the display device 11a in the electronic device 10 illustrated in FIG. 3A and FIG. 3B, for example. In that case, for example, full-color display can be achieved by superimposing an image displayed by the display portion 37a of the display device 41 and an image displayed by the display portion of the display device 11b.

The pixel 27a is described below.

In the case where the display device 41 is used instead of the display device 11b, the display portion of the display device 11b is used as the display portion 37a, and the pixel 27a includes an element displaying one color selected from red, green, and blue and an element displaying another color different from the one color.

In the case where the display device 41 is used instead of the display device 11b illustrated in FIG. 2A, the pixel 27a includes an element displaying red and an element displaying green. In the case where the display device 41 is used instead of the display device 11b illustrated in FIG. 2B, the pixel 27a includes an element displaying red and an element displaying blue.

In the case where the display device 41 is used instead of the display device 11a, the display portion of the display device 11a is used as the display portion 37a, and the pixel 27a includes an element displaying one color selected from red, green, and blue.

In the case where the display device 41 is used instead of the display device 11a illustrated in FIG. 3A, the pixel 27a includes an element displaying blue. In the case where the display device 41 is used instead of the display device 11a illustrated in FIG. 3B, the pixel 27a includes an element displaying green.

Next, the pixel 27b is described.

The pixel 27b includes an element displaying red, an element displaying green, and an element displaying blue, for example. When the pixel 27b includes a plurality of display elements and the colors of the display elements are different from each other, for example, the display portion 37b can achieve full-color display. The colors displayed by the display elements included in the pixel 27b are not limited to red, green, and blue. For example, a combination selected from a plurality of elements displaying red, green, blue, cyan, magenta, yellow, yellowish green, violet, bluish violet, orange, white, infrared, and ultraviolet light can be used. Note that the display portion 37b preferably achieves full-color display; however, a monochromatic display portion may be used as the display portion 37b. In this case, for example, the pixel 27b includes one of elements displaying red, green, blue, cyan, magenta, yellow, yellowish green, violet, bluish violet, orange, white, infrared, and ultraviolet light, for example.

The display portion 37a and the display portion 37b can be provided over the same substrate.

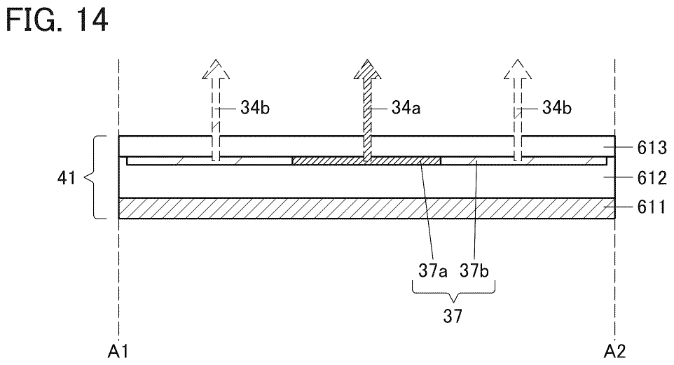

FIG. 14 is a cross-sectional view illustrating a structure example along dashed-dotted line A1-A2 in FIG. 13, and is a cross-sectional view illustrating a structure example of the display device 41 including the display portion 37a and the display portion 37b.

The display device 41 includes a substrate 611, a layer 612 over the substrate 611, and a substrate 613 over the layer 612, and the display portion 37 is provided over the layer 612. The layer 612 is provided with a driver circuit for driving the display device 41, for example. Since the driver circuit is provided with a transistor, for example, the layer 612 includes the transistor.

The display portion 37a can display an image by emitting light 34a. The display portion 37b can display an image by emitting light 34b. The light 34a and the light 34b pass through the substrate 613.

The display portion 37a is provided to include a region not overlapping with the display portion 37b. Note that part of the display portion 37a may overlap with the display portion 37b. Specifically, an end portion of the display portion 37a may overlap with the display portion 37b, and an end portion of the display portion 37b may overlap with the display portion 37a. Such a structure can prevent a region not provided with the display portion 37 being formed between the display portion 37a and the display portion 37b. Thus, a boundary between the display portion 37a and the display portion 37b can be inhibited from being recognized by the user of the electronic device 10. Here, even in the case where part of the display portion 37a overlaps with the display portion 37b, the display portion 37b can be regarded as being provided to surround the display portion 37a as long as a region of the display portion 37b that does not overlap with the display portion 37a surrounds the display portion 37a.

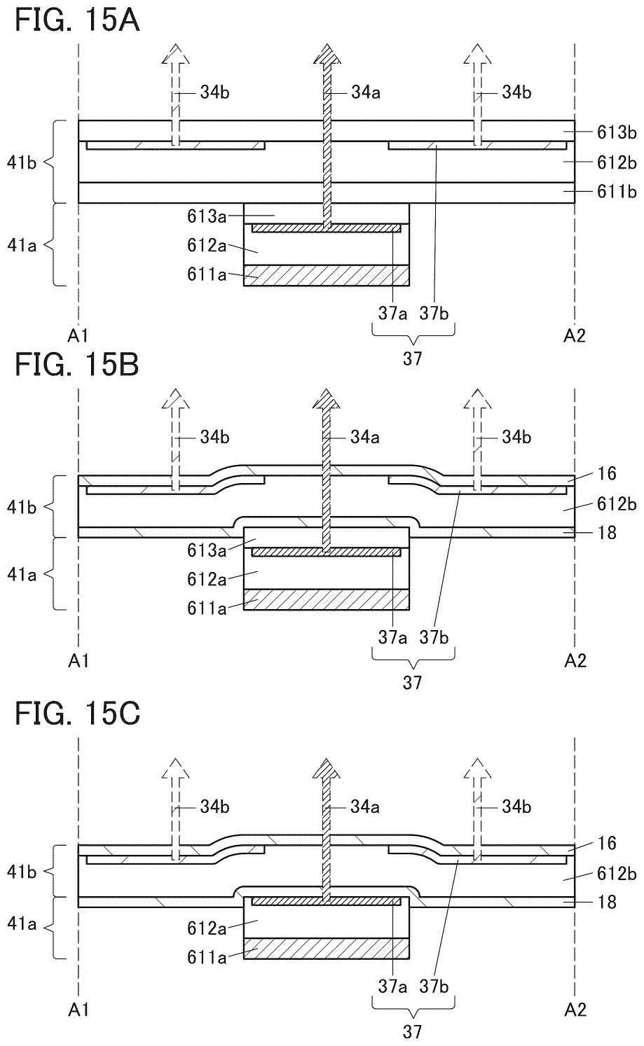

The display portion 37a and the display portion 37b may be formed over different substrates and overlap with each other as illustrated in FIG. 15A to FIG. 17B.

FIG. 15A is a cross-sectional view illustrating a structure example along dashed-dotted line A1-A2 in FIG. 13A, and is a cross-sectional view illustrating a structure example of a display device including the display portion 37. As illustrated in FIG. 15A, the display portion 37a is included in a display device 41a, and the display portion 37b is included in a display device 41b.

The display device 41a includes a substrate 611a, a layer 612a over the substrate 611a, and a substrate 613a over the layer 612a, and the display portion 37a is provided in the layer 612a. The display device 41b includes a substrate 611b, a layer 612b over the substrate 611b, and a substrate 613b over the layer 612b, and the display portion 37b is provided in the layer 612b. For example, the layer 612a is provided with a driver circuit for driving the display device 41a and the layer 612b is provided with a driver circuit for driving the display device 41b. Since these driver circuits are provided with transistors, for example, the layer 612a and the layer 612b include the transistors.

The display device 41b is provided over the display device 41a. The display device 41a overlaps with the display device 41b. Specifically, the substrate 613a overlaps with the substrate 611b, for example. For example, the substrate 613a includes a region in contact with the substrate 611b, and the display device 41a is fixed under the display device 41b. For example, when a first housing and a second housing are attached to the display device 41a and the display device 41b, respectively, and the first housing and the second housing are engaged with each other, the display device 41a can be fixed under the display device 41b. The display device 41b includes a region not overlapping with the display device 41a. Specifically, the substrate 611b includes a region not overlapping with the substrate 613a, for example.

The display portion 37a can display an image by emitting the light 34a. The display portion 37b can display an image by emitting the light 34b. The light 34a passes through the substrate 613a, the substrate 611b, the layer 612b, and the substrate 613b. The light 34b passes through the substrate 613b. Thus, the substrate 613a, the substrate 611b, the layer 612b, and the substrate 613b transmit the light 34a. The substrate 613b transmits the light 34b. Here, a structure can be employed where the substrate 611a does not transmit the light 34a or the light 34b. Thus, a structure can be employed where the substrate 611a does not transmit visible light, for example. Meanwhile, the substrate 611b, the substrate 613a, and the substrate 613b transmit visible light.

The display portion 37a is provided to include a region not overlapping with the display portion 37b. Accordingly, the light 34a entering the display device 41b can be extracted to the outside of the display device 41b even when the display portion 37b does not transmit the light 34a or the transmittance of the light 34a in the display portion 37b is lower than the transmittance of the light 34a in a region of the layer 612b where the display portion 37b is not provided. Thus, the user of the electronic device 10 including the display device 41a and the display device 41b can see an image displayed on the display portion 37a.

Note that part of the display portion 37a may overlap with the display portion 37b. Specifically, an end portion of the display portion 37a may overlap with the display portion 37b, and an end portion of the display portion 37b may overlap with the display portion 37a. Such a structure can prevent a region where the display portion 37 is not provided from being formed between the display portion 37a and the display portion 37b. Thus, a boundary between the display portion 37a and the display portion 37b can be inhibited from being recognized by the user of the electronic device 10. Here, even when part of the display portion 37a overlaps with the display portion 37b, the display portion 37b can be regarded as being provided to surround the display portion 37a as long as a region of the display portion 37b that does not overlap with the display portion 37a surrounds the display portion 37a.

As described above, in the electronic device 10, the display device 41a is provided to overlap with the display device 41b, and the display portion 37b of the display device 41b is provided to surround the display portion 37a of the display device 41a. Accordingly, loss of the light 34a can be reduced as compared with the case where the display device 41a does not overlap with the display device 41b and an image displayed on the display portion 37a and an image displayed on the display portion 37b are combined with an optical combiner such as a half mirror. In addition, loss of the light 34b can be reduced in some cases. Thus, the electronic device 10 can be an electronic device with low power consumption. The user of the electronic device 10 can see an image with high luminance.

Materials that can be used for the substrate 611, the substrate 611a, the substrate 611b, the substrate 613, the substrate 613a, or the substrate 613b are described below.

A structure can be employed where the substrate 611 does not transmit visible light. Alternatively, a structure can be employed where the substrate 611 transmits visible light. Any of substrates described below that can be used as the substrate 611a, the substrate 611b, and a later-described substrate 18 can also be used as the substrate 611.

A structure can be employed where the substrate 613 transmits visible light. Any of substrates described below that can be used as the substrate 613a, the substrate 613b, and a later-described substrate 16 can also be used as the substrate 613.

As described above, a structure can be employed where the substrate 611a does not transmit visible light, for example. Thus, a semiconductor substrate can be used as the substrate 611a. Specifically, as the substrate 611a, a single crystal semiconductor substrate or a polycrystalline semiconductor substrate using silicon, silicon carbide, or the like as a material, a compound semiconductor substrate of silicon germanium or the like, an SOI substrate, or the like can be used.

As described above, a structure is employed where the substrate 613a, the substrate 611b, and the substrate 613b transmit visible light, for example. Thus, a glass substrate, a quartz substrate, a sapphire substrate, a plastic substrate, or the like is used as the substrate 613a, the substrate 611b, and the substrate 613b, for example. Note that a glass substrate, a quartz substrate, a sapphire substrate, a plastic substrate, or the like, which is an insulating substrate, can also be used as the substrate 611a.

The thickness of each of the substrate 611a, the substrate 613a, the substrate 611b, and the substrate 613b can be greater than or equal to 50 μm and less than or equal to 2 mm, and is preferably greater than or equal to 50 μm and less than or equal to 1 mm, further preferably greater than or equal to 50 μm and less than or equal to 500 μm, still further preferably greater than or equal to 50 μm and less than or equal to 300 μm.

A variety of optical members can be arranged on a surface of the substrate 613a opposite to the display portion 37a and a surface of the substrate 613b opposite to the display portion 37b. Examples of the optical members include a polarizing plate, a retardation plate, a light diffusion layer (e.g., a diffusion film), an anti-reflective layer, and a light-condensing film.

FIG. 15B illustrates a variation example of the structure illustrated in FIG. 15A, which is different from the structure illustrated in FIG. 15A in that the display device 41b includes the substrate 18 instead of the substrate 611b and includes the substrate 16 instead of the substrate 613b.

The substrate 18 and the substrate 16 have flexibility. Thus, the display device 41b illustrated in FIG. 15B has flexibility. Therefore, the display device 41b illustrated in FIG. 15B can be regarded as a flexible display.

A flexible substrate can be thinner than a substrate without flexibility. Thus, the thickness of each of the substrate 18 and the substrate 16 can be smaller than the thickness of the substrate 611a, for example. When the display device 41b is a flexible display as described above, the difference between the height of the display portion 37b and the height of the display portion 37a relative to a surface of the substrate 611a can be small, for example. Accordingly, the difference between the distance from the eyes of the user of the electronic device 10 to the display portion 37a and the distance from the eyes of the user of the electronic device 10 to the display portion 37b can be reduced, which can inhibit one or both of an image displayed by the display portion 37a and an image displayed by the display portion 37b from being blurred. Thus, the user of the electronic device 10 can see a high-quality image.

Furthermore, reducing the difference between the height of the display portion 37b and the height of the display portion 37a relative to the surface of the substrate 611a can inhibit the light 34a emitted from the display portion 37a included in the display device 41a from entering the display portion 37b. For example, in the case where an electrode of the light-emitting element included in the display portion 37b reflects visible light, the light 34a entering the display portion 37b is reflected by the electrode and is not extracted to the outside of the display device 41b; thus, the light extraction efficiency of the display device 41a can be increased by inhibiting the light 34a from entering the display portion 37b.

Note that in the display device illustrated in FIG. 15B, the substrate 613b illustrated in FIG. 15A may be provided instead of the substrate 16. That is, only a substrate provided between the display portion 37a and the display portion 37b among the substrates included in the display device 41b may have flexibility. The substrate 613a included in the display device 41a may have flexibility. For example, the thickness of the substrate 611b illustrated in FIG. 15A may be smaller than the thickness of the substrate 611a. That is, the display device 41b may include a substrate without flexibility and the thickness of the substrate may be smaller than the thickness of the substrate 611a. Alternatively, the substrate 613a may be a substrate without flexibility and the thickness of the substrate 613a may be smaller than the thickness of the substrate 611a.

For a substrate having flexibility, any of the following can be used: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. In addition, glass that is thin enough to have flexibility may be used. Here, when the above-described material is used for the substrate, the substrate can transmit visible light.

The thickness of the flexible substrate is set in the range where both flexibility and mechanical strength can be achieved. The thickness of the flexible substrate can be greater than or equal to 1 μm and less than or equal to 300 μm, and is preferably greater than or equal to 10 μm and less than or equal to 300 μm, further preferably greater than or equal to 10 μm and less than or equal to 100 μm, still further preferably greater than or equal to 10 μm and less than or equal to 50 μm, for example. Note that the thickness of the substrate 611b illustrated in FIG. 15A may be within this range. That is, the display device 41b may include a substrate without flexibility and the thickness of the substrate may be within the above range.

In structures described below, the substrate 611b can be replaced with the substrate 18, and the substrate 613b can be replaced with the substrate 16 in some cases.

FIG. 15C illustrates a variation example of the structure illustrated in FIG. 15B, which is different from the structure illustrated in FIG. 15B in that the display device 41a does not include the substrate 613a. For example, any of the variety of optical members can be provided directly on the layer 612a, and the display device 41b can be provided thereover.

When the substrate 613a is omitted, the difference between the height of the display portion 37b and the height of the display portion 37a relative to the surface of the substrate 611a can be small, for example. Thus, the user of the electronic device 10 can see a high-quality image. Furthermore, the light 34a can be inhibited from entering the display portion 37b and the light extraction efficiency of the display device 41a can be increased. In the display device 41b illustrated in FIG. 15C, the substrate 611b may be provided instead of the substrate 18, and the substrate 613b may be provided instead of the substrate 16. That is, even when the display device 41a is not provided with the substrate 613a, a substrate provided in the display device 41b does not necessarily have flexibility

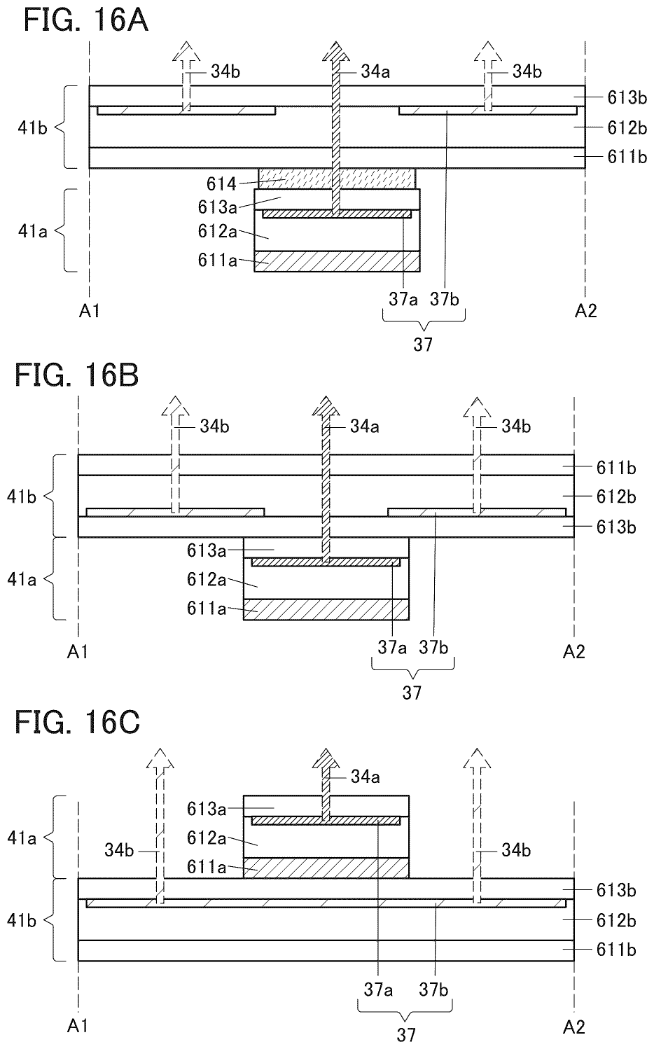

FIG. 16A illustrates a variation example of the structure illustrated in FIG. 15A, which is different from the structure illustrated in FIG. 15A in that an adhesive layer 614 is provided between the substrate 613a and the substrate 611b. The adhesive layer 614 transmits the light 34a. Thus, the adhesive layer 614 transmits visible light, for example.

When the display device 41a and the display device 41b are attached to each other with the adhesive layer 614, formation of a gap between the display device 41a and the display device 41b can be inhibited. Thus, the light 34a emitted from the display device 41a can be inhibited from being reflected or refracted by the gap. Thus, the display device 41a can display a high-quality image.

Accordingly, the adhesive layer 614 is preferably provided in a region that is over the substrate 613a and that does not overlap with the display portion 37b. In contrast, the adhesive layer 614 is not necessarily provided in a region that is over the substrate 613a and that does not overlap with the display portion 37b.

For the adhesive layer 614, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet may be used, for example.

FIG. 16B illustrates a variation example of the structure illustrated in FIG. 15A, which is different from the structure illustrated in FIG. 15A in that the substrate 613b is provided over the display device 41a, the layer 612b including the display portion 37b is provided over the substrate 613b, and the substrate 611b is provided over the layer 612b.

For example, in the display device 41b illustrated in FIG. 15A, a driver circuit is provided below the display portion 37b. Meanwhile, in the display device 41b illustrated in FIG. 16B, a driver circuit is provided above the display portion 37b. For example, in the display device 41b illustrated in FIG. 15A, the light 34b emitted from the display portion 37b passes through the substrate 613b. Meanwhile, in the display device 41b illustrated in FIG. 16B, the light 34b passes through the substrate 611b. For example, the display device 41b illustrated in FIG. 15A is a top-emission display device, and the display device 41b illustrated in FIG. 16B is a bottom-emission display device.

FIG. 16C illustrates a variation example of the structure illustrated in FIG. 15A, which is different from the structure illustrated in FIG. 15A in that the display device 41a is provided over the display device 41b. As described above, a structure can be employed where the substrate 611a does not transmit visible light, for example. Thus, the display portion 37b can be provided to overlap with the whole display portion 37a, for example. A structure can be employed where the substrate 611b does not transmit visible light, for example.

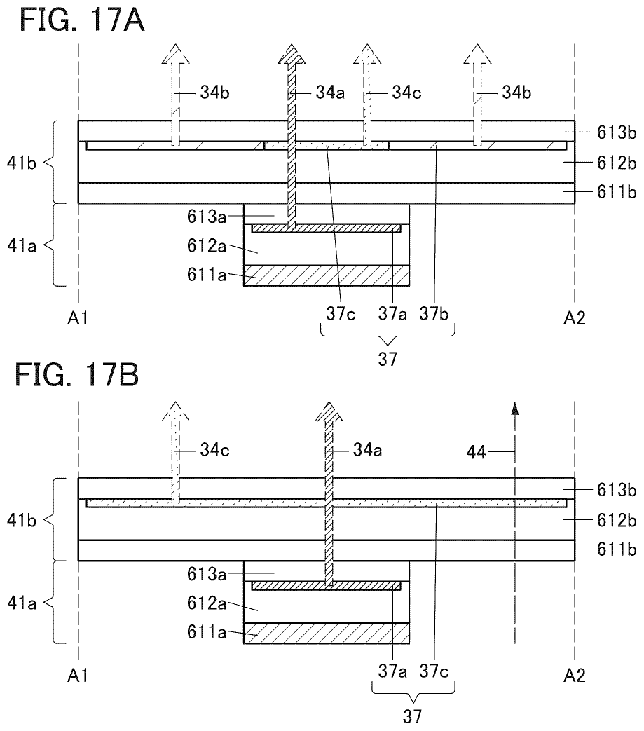

FIG. 17A illustrates a variation example of the structure illustrated in FIG. 15A, which is different from the structure illustrated in FIG. 15A in that the display portion 37c is provided in the layer 612b of the display device 41b. The display portion 37c is provided to overlap with the display portion 37a included in the display device 41a. In the structure illustrated in FIG. 17A, the display portion 37 includes the display portion 37a, the display portion 37b, and the display portion 37c. Although not illustrated, in the display portion 37c, a plurality of pixels are arranged and the pixels are arranged in a matrix, for example. The pixel includes a light-emitting element emitting visible light; when light emitted from the light-emitting element is emitted from the pixel as light 34c, an image can be displayed on the display portion 37c. Here, the pixel density of the display portion 37c can be lower than the pixel density of the display portion 37a, and can be equivalent to the pixel density of the display portion 37b. Thus, the resolution of an image displayed on the display portion 37c can be lower than the resolution of an image displayed on the display portion 37a and can be equivalent to the resolution of an image displayed on the display portion 37b.

The light 34c passes through the substrate 613b. The pixel includes a pixel circuit having a function of controlling driving of the light-emitting element. As described above, the pixel circuit includes a transistor.

In the structure illustrated in FIG. 17A, the light 34a emitted from the display portion 37a enters the display portion 37c. Thus, a structure is employed where the display portion 37c transmits the light 34a; specifically, a structure is employed where the display portion 37c has higher transmittance of the light 34a than the display portion 37b. For example, a structure is employed where the display portion 37c transmits visible light; specifically, a structure is employed where the display portion 37c has higher transmittance of visible light than the display portion 37b. For example, an electrode included in a light-emitting element provided in the display portion 37c transmits the light 34a. A layer included in the transistor of the pixel circuit provided in the display portion 37c transmits the light 34a. In the case where the pixel circuit includes a capacitor, for example, a layer included in the capacitor transmits the light 34a. Furthermore, a wiring provided in the display portion 37c also transmits the light 34a, for example. Thus, the display portion 37c can transmit the light 34a.

Accordingly, with the structure illustrated in FIG. 17A, the user of the electronic device 10 can see an image displayed by the display portion 37c of the display device 41b and an image displayed by the display portion 37a of the display device 41a which are superimposed on each other. Here, it is preferable that an image be displayed on the display portion 37a and the display portion 37c in consideration of the fact that the resolution of an image that can be displayed by the display portion 37c is lower than the resolution of an image that can be displayed by the display portion 37a. For example, a mark such as a cursor indicating a point to be focused on in an image displayed on the display portion 37a can be displayed on the display portion 37c.

FIG. 17B illustrates a variation example of the structure illustrated in FIG. 17A, which is different from the structure illustrated in FIG. 17A in that the display portion 37c includes a region not overlapping with the display portion 37a. Although FIG. 17B illustrates an example where the display device 41b does not include the display portion 37b, the display device 41b may include the display portion 37b. For example, the display portion 37b may be provided in a region not overlapping with the display device 41a. Note that in the structure illustrated in FIG. 17B, a region of the display portion 37c not overlapping with the display device 41a transmits light 44 that is external light in some cases.

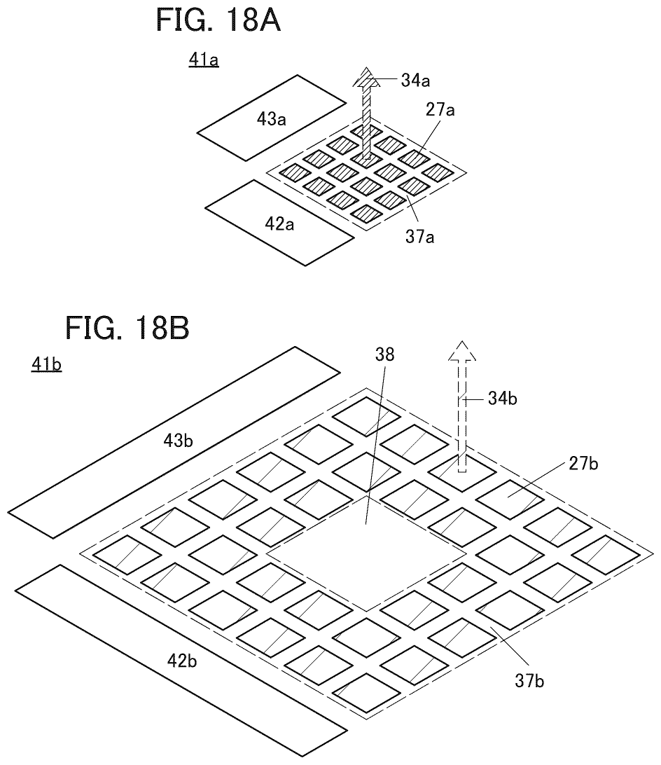

FIG. 18A is a block diagram illustrating a structure example of the display device 41a including the display portion 37a. As described above, the plurality of pixels 27a are arranged in the display portion 37a, and the pixels 27a are arranged in a matrix, for example. The pixel 27a includes one or more subpixels. The display device 41a includes a gate driver circuit 42a and a source driver circuit 43a. Although not illustrated in FIG. 18A, the gate driver circuit 42a and the source driver circuit 43a are electrically connected to the pixel 27a. The gate driver circuit 42a and the source driver circuit 43a are driver circuits of the display device 41a.

In the display device 41a, the source driver circuit 43a can write image data to the pixel 27a selected by the gate driver circuit 42a. By writing the image data to the pixel 27a, the pixel 27a emits the light 34a with luminance corresponding to the image data, whereby an image can be displayed on the display portion 37a.

FIG. 18B is a block diagram illustrating a structure example of the display device 41b including the display portion 37b. As described above, the plurality of pixels 27b are arranged in the display portion 37b. Here, a region 38 where the pixels 27b are not arranged is provided in the display device 41b, and the display portion 37b is provided to surround the region 38. The region 38 is a region overlapping with the display portion 37a of the display device 41a. Note that in the case where the display device 41b has the structure illustrated in FIG. 17A, the display portion 37b is provided in the region 38. In the case where the display device 41b has the structure illustrated in FIG. 17B, the display portion 37c is provided instead of the display portion 37b and is also provided in the region 38.

The display device 41b includes a gate driver circuit 42b and a source driver circuit 43b. Although not illustrated in FIG. 18B, the gate driver circuit 42b and the source driver circuit 43b are electrically connected to the pixel 27b. The gate driver circuit 42b and the source driver circuit 43b are driver circuits of the display device 41b.

In the display device 41b, the source driver circuit 43b can write image data to the pixel 27b selected by the gate driver circuit 42b. By writing the image data to the pixel 27b, the pixel 27b emits the light 34b with luminance corresponding to the image data, whereby an image can be displayed on the display portion 37b.

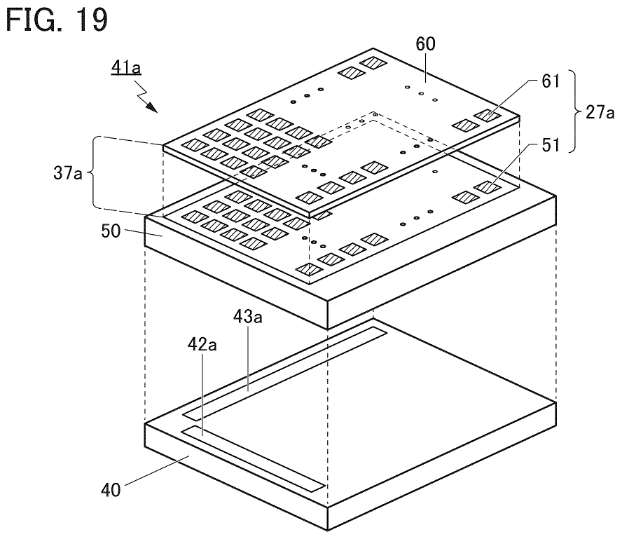

FIG. 19 is a perspective view illustrating a structure example of the display device 41a. As illustrated in FIG. 19, the display device 41a can include a layer 40, a layer 50 over the layer 40, and a layer 60 over the layer 50.

A plurality of pixel circuits 51 are arranged in the layer 50, and a plurality of light-emitting elements 61 are arranged in the layer 60. The pixel circuit 51 and the light-emitting element 61 are electrically connected to each other and function as the pixel 27a. Thus, a region where the plurality of pixel circuits 51 provided in the layer 50 and the plurality of light-emitting elements 61 provided in the layer 60 overlap with each other functions as the display portion 37a.

The gate driver circuit 42a and the source driver circuit 43a are provided in the layer 40. When the gate driver circuit 42a and the source driver circuit 43a are provided in the layer different from the layer in which the pixel circuit 51 is provided, the gate driver circuit 42a and the source driver circuit 43a can be provided to overlap with the display portion 37a. Thus, the width of the bezel around the display portion 37a can be narrowed as compared with the case where the gate driver circuit 42a and the source driver circuit 43a are provided not to overlap with the display portion 37a. Thus, the area occupied by the display portion 37a can be increased.

In addition, when the pixel circuit 51, and the gate driver circuit 42a and the source driver circuit 43a are stacked, wirings electrically connecting them can be shortened. Thus, wiring resistance and parasitic capacitance are reduced. Thus, for example, the time taken for charging and discharging a wiring can be shortened, so that the display device 41a can be driven at high speed. Furthermore, the power consumption of the electronic device 10 can be reduced because the power consumption of the display device 41a can be reduced.

Note that the gate driver circuit 42a and the source driver circuit 43a may be provided in the same layer as the pixel circuit 51. In this case, transistors included in the gate driver circuit 42a and transistors included in the source driver circuit 43a can be formed in the same step as transistors included in the pixel circuit 51, for example. Alternatively, some of the transistors included in the gate driver circuit 42a and some of the transistors included in the source driver circuit 43a may be provided in the layer 50, for example. That is, the gate driver circuit 42a and the source driver circuit 43a may be provided in both the layer 40 and the layer 50. Alternatively, one of the gate driver circuit 42a and the source driver circuit 43a may be provided in the layer 40, and the other of the gate driver circuit 42a and the source driver circuit 43a may be provided in the layer 50.

Note that a plurality of gate driver circuits 42a and a plurality of source driver circuits 43a may be provided. For example, the display portion may be divided into several sections, and the gate driver circuit and the source driver circuit may be provided for each section. In addition, the gate driver circuits and the source driver circuits can be provided to overlap with the respective sections of the display portion. In addition, the gate driver circuits and the source driver circuits can be provided so as to be close to the respective sections of the display portion.

When the plurality of driver circuits 42a are provided, wirings electrically connecting the pixel circuits 51 and the gate driver circuits 42a can be shortened. Specifically, the maximum length of the wiring from the pixel circuit 51 to the gate driver circuit 42a can be reduced. In addition, when the plurality of source driver circuits 43a are provided, wirings electrically connecting the pixel circuits 51 and the source driver circuits 43a can be shortened. Specifically, the maximum length of the wiring from the pixel circuit 51 to the source driver circuit 43a can be reduced. Thus, wiring resistance and parasitic capacitance are reduced. Thus, for example, the time taken for charging and discharging a wiring can be shortened, so that the display device 41a can be driven at high speed. Furthermore, the power consumption of the electronic device 10 can be reduced because the power consumption of the display device 41a can be reduced. Furthermore, the number of rows of the pixel circuits 51 to be scanned by one gate driver circuit 42a can be reduced, for example; thus, the frame frequency of the display device 41a can be increased.

The gate driver circuit 42a may include a region overlapping with the source driver circuit 43a. When the gate driver circuit 42a includes a region overlapping with the source driver circuit 43a, the layout flexibility of the gate driver circuit 42a and the source driver circuit 43a can be increased. By contrast, when the gate driver circuit 42a and the source driver circuit 43a do not overlap with each other, the driving of the gate driver circuit 42a and the driving of the source driver circuit 43a can be inhibited from influencing each other.

At least part of this embodiment can be implemented in appropriate combination with the other embodiments described in this specification.

### Embodiment 4

In this embodiment, display devices of embodiments of the present invention will be described.

### [Display Module]

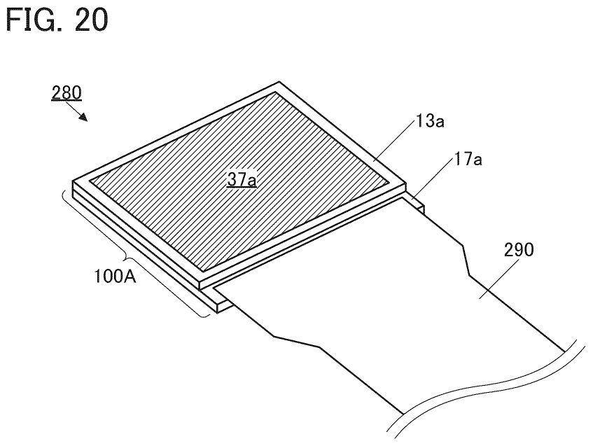

FIG. 20 is a perspective view of a display module 280. The display module 280 includes a display device 100A and an FPC 290. Note that the display device included in the display module 280 is not limited to the display device 100A and may be any of a display device 100C to a display device 100G described later. The display device 100A to the display device 100G can be suitably used as the display device 41a described in Embodiment 1. FIG. 20 illustrates a substrate 17a, the display portion 37a, and a substrate 13a among components of the display device 100A.

The FPC 290 functions as a wiring for supplying a data signal, a power supply potential, or the like to the display device 100A from the outside. An IC may be mounted on the FPC 290.

For the substrate 17a and the substrate 13a, the substrate described in the above embodiment can be referred to as appropriate.

### [Display Device 100A]

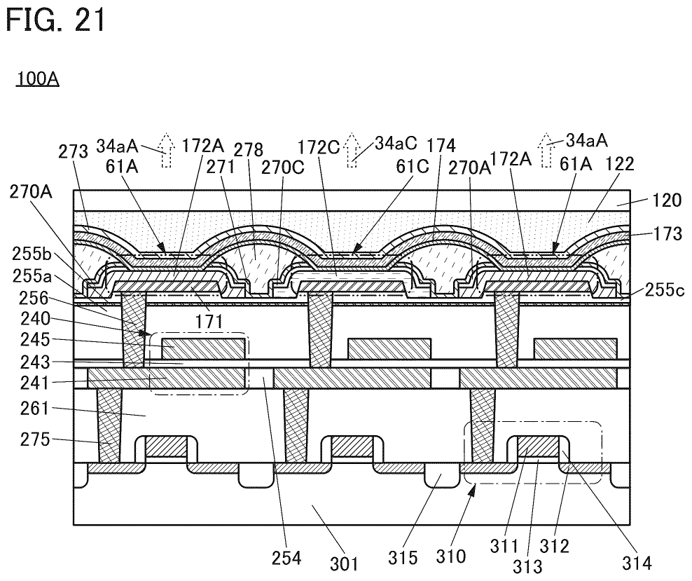

FIG. 21 is a cross-sectional view illustrating a structure example of the display device 100A, specifically, a cross-sectional view illustrating a structure example of a pixel included in the display device 100A. The display device 100A includes a substrate 301, a light-emitting element 61A, a light-emitting element 61C, a capacitor 240, and a transistor 310.

The substrate 301 corresponds to the substrate 17a in FIG. 20. The transistor 310 is a transistor including a channel formation region in the substrate 301. The transistor 310 includes part of the substrate 301, a conductive layer 311, a pair of low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The pair of low-resistance regions 312 are regions where the substrate 301 is doped with an impurity, and function as a source and a drain. The insulating layer 314 is provided to cover the side surface of the conductive layer 311.

An element isolation layer 315 is provided between two adjacent transistors 310 so as to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 275 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240, an insulating layer 255b is provided over the insulating layer 255a, and an insulating layer 255c is provided over the insulating layer 255b. The light-emitting element 61A and the light-emitting element 61C are provided over the insulating layer 255c. The light-emitting element 61A emits light 34aA, and the light-emitting element 61C emits light 34aC.

An insulator is provided in a region between adjacent light-emitting elements 61. For example, in FIG. 21, a protective layer 271 and an insulating layer 278 over the protective layer 271 are provided in the region.

An EL layer 172A is provided to cover the top and side surfaces of the conductive layer 171 included in the light-emitting element 61A, and an EL layer 172C is provided to cover the top and side surfaces of the conductive layer 171 included in the light-emitting element 61C. A layer 270A is positioned over the EL layer 172A, and a layer 270C is positioned over the EL layer 172C. The layer 270A and the layer 270C are each a remaining part of a protective layer (also referred to as a mask layer or a sacrificial layer) for protecting the EL layer 172A and the EL layer 172C at the time of etching the EL layer 172A and the EL layer 172C.

The conductive layer 171 is electrically connected to one of the source and the drain of the transistor 310 through a plug 256 embedded in the insulating layer 243, the insulating layer 255a, the insulating layer 255b, and the insulating layer 255c, the conductive layer 241 embedded in the insulating layer 254, and the plug 275 embedded in the insulating layer 261. The top surface of the insulating layer 255c and the top surface of the plug 256 are level or substantially level with each other. A variety of conductive materials can be used for the plugs.

A protective layer 273 is provided over the light-emitting element 61A and the light-emitting element 61C. A substrate 120 is attached to the protective layer 273 with an adhesive layer 122. The substrate 120 corresponds to the substrate 13a in FIG. 20.

The light-emitting element 61A and the light-emitting element 61C may be light-emitting elements exhibiting different colors or may be light-emitting elements exhibiting the same color.

The light-emitting element 61A and the light-emitting element 61C can employ any of the structures of the light-emitting element 110B, the light-emitting element 110R, and the light-emitting element 110G described in the above embodiment.

The pixel electrode 111 described in the above embodiment can be used as the conductive layer 171. For the EL layer 172A and the EL layer 172C, any one of the organic layers 112B, 112R, and 112G described in the above embodiment can be referred to. For the common layer 174, the common layer 114 described in the above embodiment can be referred to. For the conductive layer 173, the common electrode 113 described in the above embodiment can be referred to. For the protective layer 271, the insulating layer 125 described in the above embodiment can be referred to. For the insulating layer 278, the resin layer 126 described in the above embodiment can be referred to. For the layer 270A and the layer 270C, the layer 128 described in the above embodiment can be referred to.

A light-blocking layer may be provided on the surface of the substrate 120 on the adhesive layer 122 side. Any of a variety of optical members can be provided on the outer surface of the substrate 120. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 120. For example, a glass layer or a silica layer (SiOₓ layer) is preferably provided as the surface protective layer to inhibit the surface contamination and generation of a scratch. The surface protective layer may be formed using DLC (diamond-like carbon), aluminum oxide (AlOₓ), a polyester-based material, a polycarbonate-based material, or the like. For the surface protective layer, a material having high visible-light transmittance is preferably used. The surface protective layer is preferably formed using a material with high hardness.

In the case where a circularly polarizing plate overlaps with the display device, a highly optically isotropic substrate is preferably used as the substrate included in the display device. A highly optically isotropic substrate has a low birefringence. Note that a highly optically isotropic substrate can be regarded as having a small amount of birefringence.

The absolute value of a retardation (phase difference) of a highly optically isotropic substrate is preferably less than or equal to 30 nm, further preferably less than or equal to 20 nm, still further preferably less than or equal to 10 nm.

Examples of a film having high optical isotropy include a triacetyl cellulose (TAC, also referred to as cellulose triacetate) film, a cycloolefin polymer (COP) film, a cycloolefin copolymer (COC) film, and an acrylic film.

In the case where a film is used for the substrate and the film absorbs water, the shape of the display device might be changed, e.g., creases are generated. Thus, for the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

### [Display Device 100C]

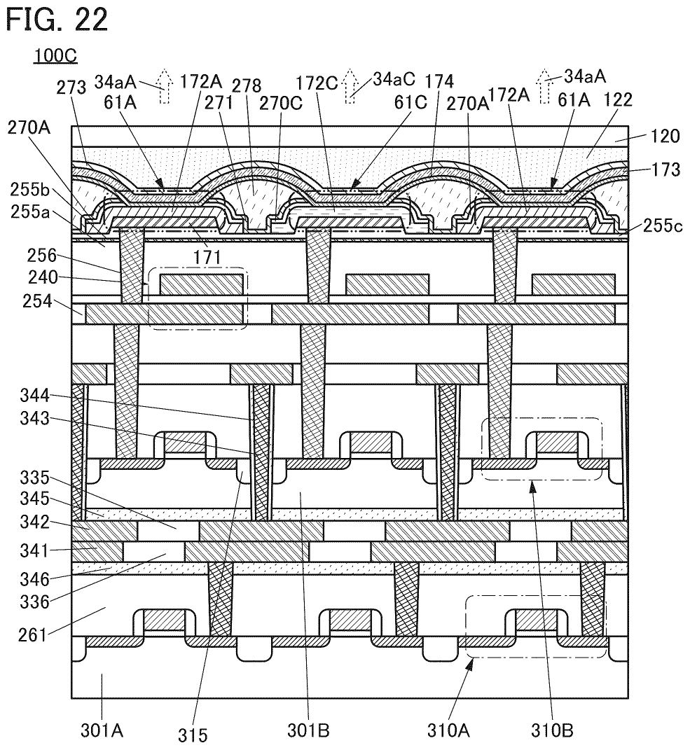

The display device 100C illustrated in FIG. 22 has a structure where the transistor 310A and a transistor 310B in each of which a channel is formed in a semiconductor substrate are stacked. Note that in the description of the display device below, portions similar to those of the aforementioned display device are not described in some cases.

The display device 100C has a structure where a substrate 301B provided with the transistor 310B, the capacitor 240, and the light-emitting elements 61 is attached to a substrate 301A provided with the transistor 310A.

Here, an insulating layer 345 is preferably provided on the bottom surface of the substrate 301B. An insulating layer 346 is preferably provided over the insulating layer 261 provided over the substrate 301A. The insulating layer 345 and the insulating layer 346 are insulating layers functioning as protective layers and can inhibit diffusion of impurities into the substrate 301B and the substrate 301A. For the insulating layer 345 and the insulating layer 346, an inorganic insulating film that can be used for the protective layer 273 can be used.

The substrate 301B is provided with a plug 343 penetrating the substrate 301B and the insulating layer 345. An insulating layer 344 is preferably provided to cover the side surface of the plug 343. The insulating layer 344 is an insulating layer functioning as a protective layer and can inhibit diffusion of impurities into the substrate 301B. As the insulating layer 344, an inorganic insulating film that can be used as the protective layer 273 can be used.

In addition, a conductive layer 342 is provided under the insulating layer 345 on the substrate 301B. The conductive layer 342 is preferably provided to be embedded in an insulating layer 335. The bottom surfaces of the conductive layer 342 and the insulating layer 335 are preferably planarized. Here, the conductive layer 342 is electrically connected to the plug 343. On the other hand, a conductive layer 341 is provided over the insulating layer 346 over the substrate 301A. The conductive layer 341 is preferably provided to be embedded in an insulating layer 336. The top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the planarity of a plane formed by the conductive layer 342 and the insulating layer 335 and a plane formed by the conductive layer 341 and the insulating layer 336 allows the conductive layer 341 and the conductive layer 342 to be attached to each other favorably.

The conductive layer 341 and the conductive layer 342 are preferably formed using the same conductive material. For example, it is possible to use a metal film containing an element selected from Al, Cr, Cu, Ta, Ti, Mo, and W, or a metal nitride film containing any of the above elements as a component (e.g., a titanium nitride film, a molybdenum nitride film, or a tungsten nitride film). Copper is particularly preferably used for the conductive layer 341 and the conductive layer 342. In that case, it is possible to employ Cu-to-Cu (copper-to-copper) direct bonding technique (a technique for achieving electrical continuity by connecting Cu (copper) pads).

### [Display Device 100D]

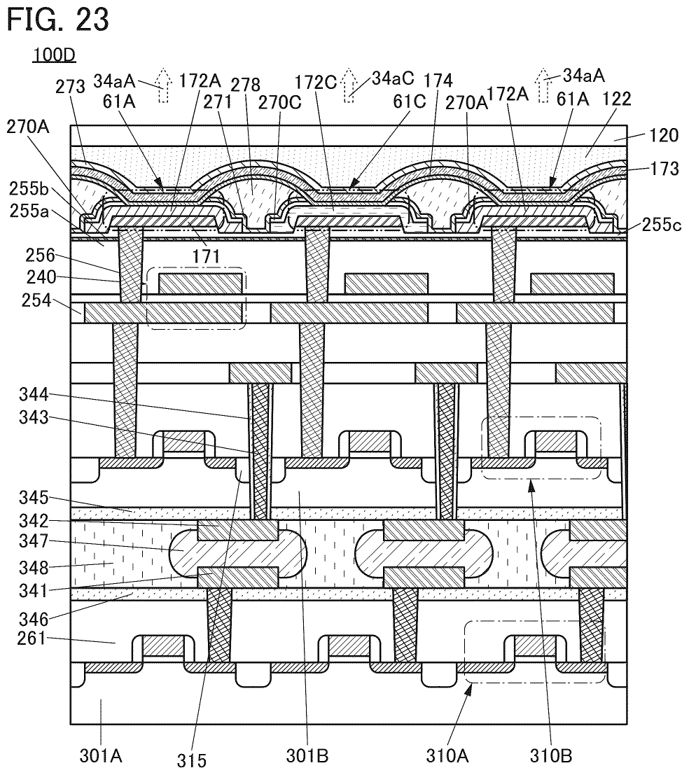

The display device 100D illustrated in FIG. 23 has a structure where the conductive layer 341 and the conductive layer 342 are bonded to each other through a bump 347.

As illustrated in FIG. 23, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. As another example, solder may be used for the bump 347. An adhesive layer 348 may be provided between the insulating layer 345 and the insulating layer 346. In the case where the bump 347 is provided, the insulating layer 335 and the insulating layer 336 may be omitted.

### [Display Device 100E]

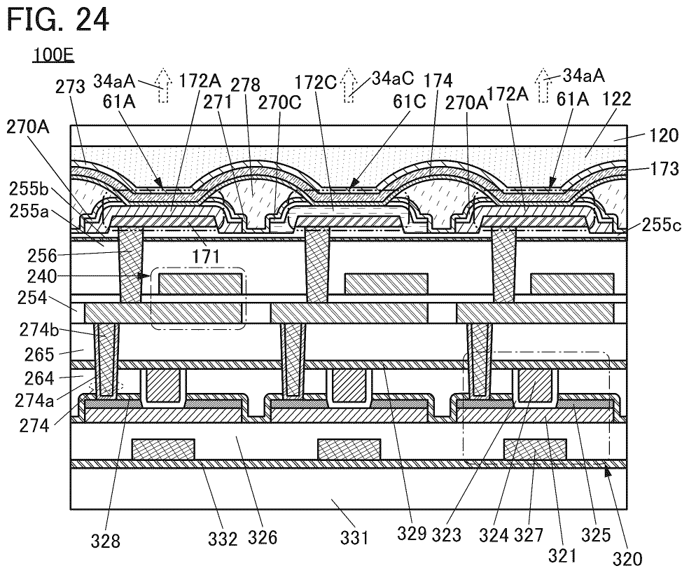

The display device 100E illustrated in FIG. 24 differs from the display device 100A mainly in a structure of a transistor.

A transistor 320 is an OS transistor. The transistor 320 includes a semiconductor layer 321, an insulating layer 323, a conductive layer 324, a pair of conductive layers 325, an insulating layer 326, and a conductive layer 327.

A substrate 331 corresponds to the substrate 17a in FIG. 20. As the substrate 331, an insulating substrate or a semiconductor substrate can be used.

An insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 321 to the insulating layer 332 side. As the insulating layer 332, it is possible to use, for example, a film in which hydrogen or oxygen is less likely to diffuse than in a silicon oxide film, such as an aluminum oxide film, a hafnium oxide film, or a silicon nitride film.

The conductive layer 327 is provided over the insulating layer 332, and the insulating layer 326 is provided so as to cover the conductive layer 327. The conductive layer 327 functions as a first gate electrode of the transistor 320, and part of the insulating layer 326 functions as a first gate insulating layer. An oxide insulating film such as a silicon oxide film is preferably used for a region of the insulating layer 326 that is in contact with at least the semiconductor layer 321. The top surface of the insulating layer 326 is preferably planarized.

The semiconductor layer 321 is provided over the insulating layer 326. The semiconductor layer 321 preferably includes a metal oxide film having semiconductor characteristics. The pair of conductive layers 325 is provided over and in contact with the semiconductor layer 321 and functions as a source electrode and a drain electrode.

An insulating layer 328 is provided to cover the top and side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 or the like into the semiconductor layer 321 and release of oxygen from the semiconductor layer 321. For the insulating layer 328, an insulating film similar to the insulating layer 332 can be used.

An opening reaching the semiconductor layer 321 is provided in the insulating layer 328 and the insulating layer 264. The inside of the opening is filled with the insulating layer 323 that is in contact with the side surfaces of the insulating layer 264, the insulating layer 328, and the conductive layer 325 and the top surface of the semiconductor layer 321, and the conductive layer 324 over the insulating layer 323. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are level or substantially level with each other, and an insulating layer 329 and an insulating layer 265 are provided to cover these layers.

The insulating layer 264 and the insulating layer 265 function as interlayer insulating layers. The insulating layer 329 functions as a barrier layer that prevents diffusion of impurities such as water and hydrogen from the insulating layer 265 and the like into the transistor 320. For the insulating layer 329, an insulating film similar to the insulating layer 328 and the insulating layer 332 can be used.

A plug 274 electrically connected to one of the pair of conductive layers 325 is provided so as to be embedded in the insulating layer 265, the insulating layer 329, the insulating layer 264, and the insulating layer 328. Here, the plug 274 preferably includes a conductive layer 274a covering the side surface of an opening formed in the insulating layer 265, the insulating layer 329, the insulating layer 264, and the insulating layer 328 and part of the top surface of the conductive layer 325, and a conductive layer 274b in contact with the top surface of the conductive layer 274a. In that case, for the conductive layer 274a, a conductive material in which hydrogen and oxygen are less likely to diffuse is preferably used.

### [Display Device 100F]

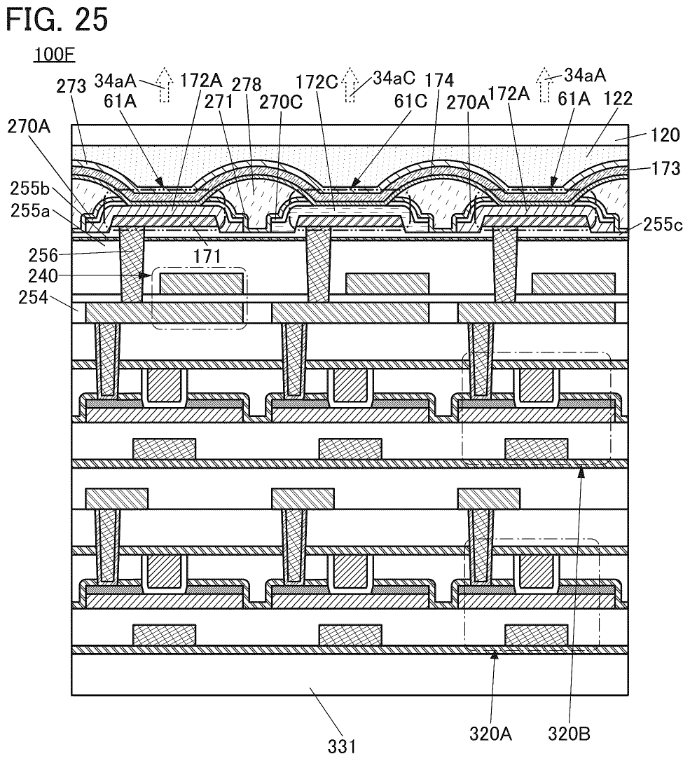

The display device 100F illustrated in FIG. 25 has a structure where a transistor 320A and a transistor 320B each including an oxide semiconductor in a semiconductor where a channel is formed are stacked.

The description of the display device 100E can be referred to for the transistor 320A, the transistor 320B, and the components around them.

Although the structure where two transistors including an oxide semiconductor are stacked is described here, the present invention is not limited thereto. For example, three or more transistors may be stacked.

### [Display Device 100G]

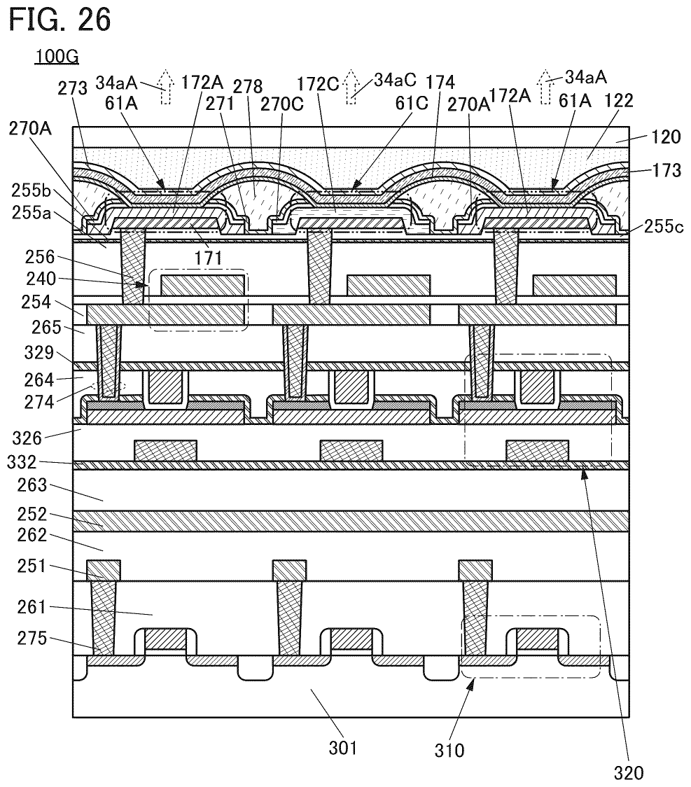

The display device 100G illustrated in FIG. 26 has a structure where the transistor 310 having a channel formed in the substrate 301 and the transistor 320 including a metal oxide in a semiconductor layer where a channel is formed are stacked.

The insulating layer 261 is provided so as to cover the transistor 310, and a conductive layer 251 is provided over the insulating layer 261. An insulating layer 262 is provided so as to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided so as to cover the transistor 320, and the capacitor 240 is provided over the insulating layer 265. The capacitor 240 and the transistor 320 are electrically connected to each other through the plug 274.

The transistor 320 can be used as a transistor included in a pixel circuit. In addition, the transistor 310 can be used as a transistor included in a pixel circuit or a transistor included in a driver circuit for driving the pixel circuit (e.g., a gate driver circuit or a source driver circuit). The transistor 310 and the transistor 320 can also be used as transistors included in a variety of circuits such as an arithmetic circuit and a memory circuit.

With such a structure, not only the pixel circuit but also the driver circuit, for example, can be formed directly under the light-emitting elements; thus, the display device can be downsized as compared with the case where a driver circuit is provided around a display region.

### [Display Device 100H]

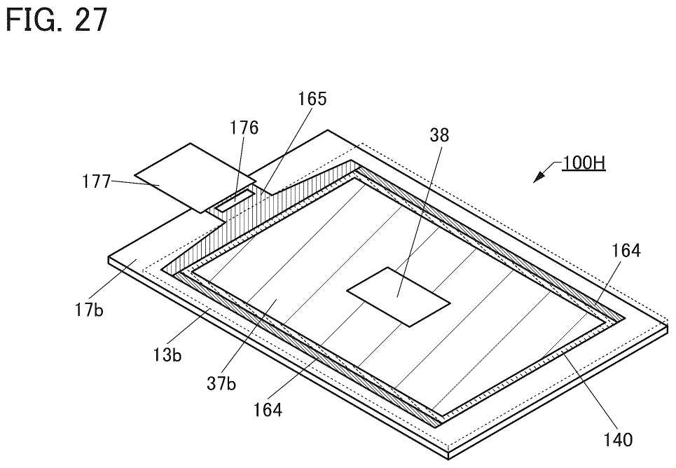

FIG. 27 is a perspective view of a display device 100H. The display device 100H can be suitably used as the display device 41b described in Embodiment 3.

The display device 100H has a structure where the substrate 13b and the substrate 17b are attached to each other. In FIG. 27, the substrate 13b is denoted by a dashed line. For the substrate 17b and the substrate 13b, the substrate described in the above embodiment can be referred to as appropriate.

The display device 100H includes the display portion 37b, the connection portion 140, a circuit 164, a wiring 165, and the like. FIG. 27 illustrates an example where an IC 176 and an FPC 177 are mounted on the display device 100H. Thus, the structure illustrated in FIG. 27 can also be regarded as a display module including the display device 100H, the IC (integrated circuit), and the FPC. Here, a display device in which a substrate is equipped with a connector such as an FPC or mounted with an IC is referred to as a display module.

The display portion 37b is provided to surround the region 38. The region 38 is a region where no image is displayed. Here, the display portion 37c described in Embodiment 1 may be provided in the region 38. The display portion 37c may be provided instead of the display portion 37b, and the display portion 37c may also be provided in the region 38. Furthermore, the display portion 37b may be provided not only outside the region 38 but also inside the region 38.

The connection portion 140 is provided outside the display portion 37b. The connection portion 140 can be provided along one side or a plurality of sides of the display portion 37b. The number of connection portions 140 may be one or more. FIG. 27 illustrates an example where the connection portion 140 is provided to surround the four sides of the display portion 37b. A common electrode of a light-emitting element is electrically connected to a conductive layer in the connection portion 140, so that a potential can be supplied to the common electrode.

As the circuit 164, a gate driver circuit can be used, for example.

A signal and power can be supplied to the pixel portion 37b and the circuit 164 through the wiring 165. The signal and power are input to the wiring 165 from the outside through the FPC 177 or from the IC 176.

FIG. 27 illustrates an example where the IC 176 is provided over the substrate 17b by a COG (Chip On Glass) method, a COF (Chip On Film) method, or the like. As the IC 176, an IC functioning as a gate driver circuit, a source driver circuit, or the like can be used. Note that the display device 100H and the display module are not necessarily provided with an IC. The IC may be mounted on the FPC by a COF method, for example.

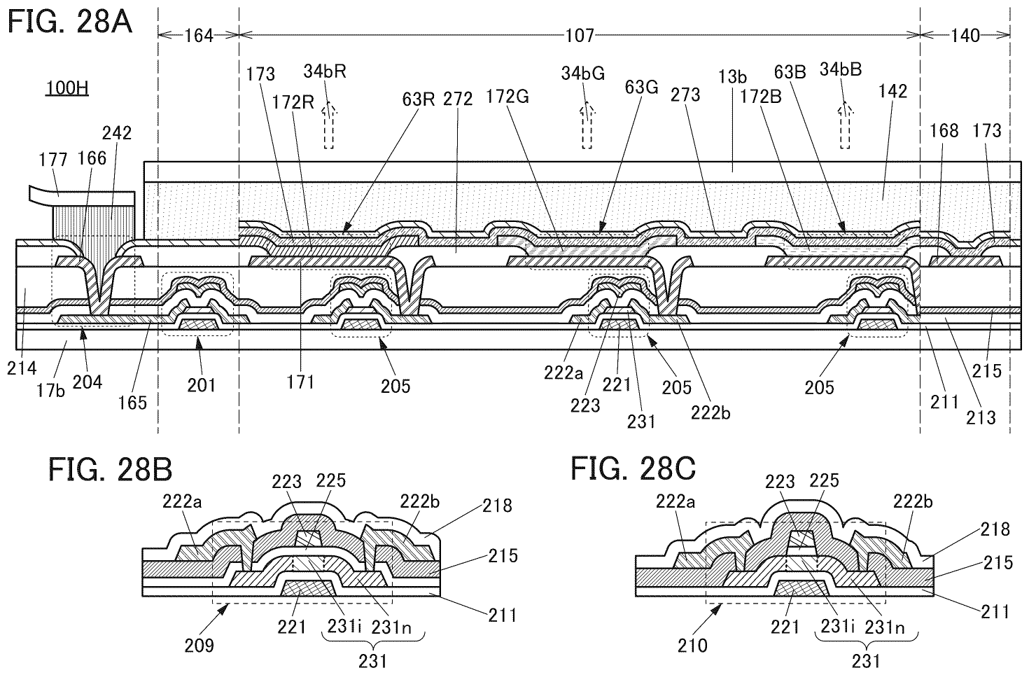

FIG. 28A illustrates an example of cross sections of part of a region including the FPC 177, part of the circuit 164, part of a display portion 107, part of the connection portion 140, and part of a region including an end portion of the display device 100H. Here, the structure of the display portion 107 can be employed for the display portion 37b illustrated in FIG. 27. In the case where the display portion 37c described in Embodiment 1 is provided in the region 38, the structure of the display portion 107 can be employed for the display portion 37c.

The display device 100H illustrated in FIG. 28A includes a transistor 201, a transistor 205, a light-emitting element 63R emitting red light 34bR, a light-emitting element 63G emitting green light 34bG, a light-emitting element 63B emitting blue light 34bB, and the like between the substrate 17b and the substrate 13b. Note that any of a variety of optical members can be arranged on the outer surface of the substrate 13b. Examples of the optical members include a polarizing plate, a retardation plate, a light diffusion layer (e.g., a diffusion film), an anti-reflective layer, and a light-condensing film.

The light-emitting element 63R includes the conductive layer 171, an EL layer 172R over the conductive layer 171, and the conductive layer 173 over the EL layer 172R. The light-emitting element 63G includes the conductive layer 171, an EL layer 172G over the conductive layer 171, and the conductive layer 173 over the EL layer 172G. The light-emitting element 63B includes the conductive layer 171, an EL layer 172B over the conductive layer 171, and the conductive layer 173 over the EL layer 172B. The organic layers 112R, 112G, and 112B can be referred to for the EL layer 172R, the EL layer 172G, and the EL layer 172B, respectively.

The conductive layer 171 which functions as a pixel electrode and is included in each of the light-emitting element 63R, the light-emitting element 63G, and the light-emitting element 63B is electrically connected to a conductive layer 222b included in the transistor 205 through an opening provided in an insulating layer 214. The conductive layer 171 is provided along the opening in the insulating layer 214. Thus, a depressed portion is provided in the conductive layer 171.

FIG. 28H illustrates an example where the insulating layer 272 is provided to cover an end portion of the conductive layer 171. The insulating layer 272 can be provided to fill the depression portion of the conductive layer 171. Although FIG. 28H illustrates a structure example where the insulating layer 272 covers the end portion of the conductive layer 171, a structure where the end portion of the conductive layer 171 is not covered with an insulating layer may be employed. For example, as illustrated in FIG. 11A, FIG. 11B, and the like, a structure may be employed where the end portion of the conductive layer functioning as the pixel electrode is not covered with the insulating layer, the end portion of the conductive layer functioning as the pixel electrode is covered with the organic layer, and an insulating layer is provided between the organic layers of the adjacent light-emitting elements.

The protective layer 273 is provided over the light-emitting element 63R, the light-emitting element 63G, and the light-emitting element 63B. The protective layer 273 and the substrate 13b are bonded to each other with an adhesive layer 142. A solid sealing structure, a hollow sealing structure, or the like can be employed for sealing the light-emitting element 63R, the light-emitting element 63G, and the light-emitting element 63B. In FIG. 28A, a solid sealing structure is employed where a space between the substrate 13b and the substrate 17b is filled with the adhesive layer 142. Alternatively, a hollow sealing structure where the space is filled with an inert gas (e.g., nitrogen or argon) may be employed. In that case, the adhesive layer 142 may be provided not to overlap with the light-emitting elements. The space may be filled with a resin different from that of the frame-like adhesive layer 142.

FIG. 28A illustrates an example where the connection portion 140 includes a conductive layer 168 obtained by processing the same conductive film as a conductive film to be the conductive layer 171. The conductive layer 168 is supplied with a power supply potential and is electrically connected to the conductive layer 173 functioning as a common electrode. Thus, a power supply potential can be supplied to the conductive layer 173 through the conductive layer 168.

The display device 100H has a top-emission structure. Light emitted from the light-emitting element is emitted toward the substrate 13b side. The conductive layer 171 functioning as a pixel electrode contains a material that reflects visible light, and the conductive layer 173 functioning as a common electrode contains a material that transmits visible light.

Both the transistor 201 and the transistor 205 are formed over the substrate 17b. These transistors can be manufactured using the same material in the same process.

An insulating layer 211, an insulating layer 213, an insulating layer 215, and the insulating layer 214 are provided in this order over the substrate 17b. Part of the insulating layer 211 functions as a first gate insulating layer of each transistor. Part of the insulating layer 213 functions as a second gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or more.

A material in which impurities such as water and hydrogen do not easily diffuse is preferably used for at least one of the insulating layers covering the transistors. This allows the insulating layer to function as a barrier layer. Such a structure can effectively inhibit diffusion of impurities into the transistors from the outside and can increase the reliability of the display device.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used, for example. Alternatively, a hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The outermost layer of the insulating layer 214 preferably has a function of an etching protective layer. Thus, the formation of a depression portion in the insulating layer 214 can be inhibited in processing the conductive film to be the conductive layer 171, for example. Note that the insulating layer 214 may be provided with a depressed portion in processing the conductive film to be the conductive layer 171, for example.

Each of the transistor 201 and the transistor 205 includes a conductive layer 221 functioning as a gate, the insulating layer 211 functioning as a first gate insulating layer, a conductive layer 222a and the conductive layer 222b functioning as a source and a drain, a semiconductor layer 231, the insulating layer 213 functioning as a second gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display device of this embodiment. For example, a planar transistor, a staggered transistor, an inverted staggered transistor, or the like can be used. A top-gate or a bottom-gate transistor structure may be employed. Alternatively, gates may be provided above and below the semiconductor layer where a channel is formed.

The transistor 201 and the transistor 205 employ a structure where the semiconductor layer where a channel is formed is provided between two gates. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor layer of each of the transistors, and an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case degradation of the transistor characteristics can be inhibited.

The semiconductor layer of the transistor preferably includes a metal oxide. That is, an OS transistor is preferably used as the transistor included in the display device of this embodiment.

Examples of the metal oxide that can be used for the semiconductor layer include indium oxide, gallium oxide, and zinc oxide. The metal oxide preferably contains two or three selected from indium, an element M, and zinc. The element Mis one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. In particular, the element M is preferably one or more kinds selected from aluminum, gallium, yttrium, and tin.

It is particularly preferable that an oxide containing indium (In), gallium (Ga), and zinc (Zn) (also referred to as IGZO) be used as the metal oxide used for the semiconductor layer. Alternatively, it is preferable to use an oxide containing indium, tin, and zinc (also referred to as ITZO (registered trademark)). Alternatively, it is preferable to use an oxide containing indium, gallium, tin, and zinc. Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO).

In the case where the metal oxide used for the semiconductor layer is an In-M-Zn oxide, the atomic proportion of In is preferably higher than or equal to the atomic proportion of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of +30% of an intended atomic ratio.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

The semiconductor layer may include two or more metal oxide layers having different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being formed over the first metal oxide layer can be suitably employed. Gallium or aluminum is preferably used as the element M.

Alternatively, a stacked-layer structure of one selected from indium oxide, indium gallium oxide, and IGZO, and one selected from IAZO, IAGZO, and ITZO (registered trademark) may be employed, for example.

As the oxide semiconductor having crystallinity, a CAAC (c-axis aligned crystalline)-OS, an nc (nanocrystalline)-OS, and the like can be given.

Alternatively, a transistor containing silicon in its channel formation region (a Si transistor) may be used. As silicon, single crystal silicon, polycrystalline silicon, amorphous silicon, and the like can be given. In particular, a transistor containing low-temperature polysilicon (LTPS) in a semiconductor layer (such a transistor is referred to as an LTPS transistor) can be used. The LTPS transistor has high field-effect mobility and excellent frequency characteristics.

With the use of a Si transistor such as an LTPS transistor, a circuit required to be driven at a high frequency (e.g., a data driver circuit) can be formed on the same substrate as the display portion. Thus, external circuits mounted on the display device can be simplified, and parts costs and mounting costs can be reduced.

An OS transistor has much higher field-effect mobility than a transistor using amorphous silicon. In addition, an OS transistor has an extremely low leakage current between a source and a drain in an off state (hereinafter also referred to as off-state current), and charge accumulated in a capacitor that is connected in series to the transistor can be retained for a long period. Furthermore, power consumption of the display device can be reduced with the use of an OS transistor.

To increase the emission luminance of the light-emitting element included in the pixel circuit, the amount of current made flow through the light-emitting element needs to be increased. For this, it is necessary to increase the source-drain voltage of a driving transistor included in the pixel circuit. Since an OS transistor has a higher withstand voltage between the source and the drain than a Si transistor, a high voltage can be applied between the source and the drain of the OS transistor. Accordingly, when an OS transistor is used as the driving transistor included in the pixel circuit, the amount of current flowing through the light-emitting element can be increased, so that the emission luminance of the light-emitting element can be increased.

When a transistor is driven in a saturation region, a change in source-drain current relative to a change in gate-source voltage can be smaller in an OS transistor than in a Si transistor. Accordingly, when an OS transistor is used as the driving transistor included in the pixel circuit, current flowing between the source and the drain can be minutely determined by controlling the gate-source voltage. Thus, the amount of current flowing through the light-emitting element can be controlled. Accordingly, the number of gray levels in the pixel circuit can be increased.

Regarding saturation characteristics of current flowing when a transistor is driven in a saturation region, even in the case where the source-drain voltage of an OS transistor increases gradually, more stable current (saturation current) can be made flow through an OS transistor than through a Si transistor. Thus, by using an OS transistor as the driving transistor, a stable current can be made flow through light-emitting elements even when the current-voltage characteristics of the organic EL devices vary, for example. In other words, when the OS transistor is driven in the saturation region, the source-drain current hardly changes with an increase in the source-drain voltage. Hence, the emission luminance of the light-emitting element can be stable.

As described above, with the use of an OS transistor as a driving transistor included in the pixel circuit, it is possible to inhibit black-level degradation, increase the luminance, increase the number of gray levels, and suppress variations in light-emitting elements, for example.

The transistors included in the circuit 164 and the transistors included in the display portion 37b may have the same structure or different structures. One structure or two or more types of structures may be employed for a plurality of transistors included in the circuit 164. Similarly, one structure or two or more types of structures may be employed for a plurality of transistors included in the display portion 37b.

All the transistors included in the display portion 37b may be OS transistors or all the transistors included in the display portion 37b may be Si transistors. Alternatively, some of the transistors included in the display portion 37b may be OS transistors and the others may be Si transistors.

For example, when both an LTPS transistor and an OS transistor are used in the display portion 37b, the display device can have low power consumption and high driving capability. A structure where an LTPS transistor and an OS transistor are used in combination is referred to as LTPO in some cases. For example, preferably, an OS transistor is used as a transistor functioning as a switch for controlling conduction and non-conduction between wirings and an LTPS transistor is used as a transistor for controlling current.

For example, one of the transistors included in the display portion 37b functions as a transistor for controlling a current flowing through the light-emitting element and can be referred to as a driving transistor. One of a source and a drain of the driving transistor is electrically connected to the pixel electrode of the light-emitting element. An LTPS transistor is preferably used as the driving transistor. In that case, the amount of current flowing through the light-emitting element can be increased.

Another transistor included in the display portion 37b functions as a switch for controlling selection and non-selection of a pixel and can also be referred to as a selection transistor. A gate of the selection transistor is electrically connected to a gate line, and one of a source and a drain thereof is electrically connected to a data line. An OS transistor is preferably used as the selection transistor. In that case, the gray level of the pixel can be maintained even with an extremely low frame frequency (e.g., lower than or equal to 1 fps); thus, power consumption can be reduced by stopping the driver in displaying a still image.

As described above, the display device of one embodiment of the present invention can have all of a high aperture ratio, a high resolution, high display quality, and low power consumption.

Note that the display device of one embodiment of the present invention has a structure including the OS transistor and the light-emitting element having an MML structure. With this structure, the leakage current that might flow through the transistor and the leakage current that might flow between adjacent light-emitting elements can be extremely low. With the structure, a viewer can notice any one or more of the image crispness, the image sharpness, a high chroma, and a high contrast ratio in an image displayed on the display device. When the leakage current that might flow through the transistor and the lateral leakage current between the light-emitting elements are extremely low, light leakage that might occur in black display (what is called black-level degradation) or the like can be minimized, for example.

In particular, in the case where a light-emitting element having the MML structure employs the above-described SBS structure, a layer provided between light-emitting elements is disconnected; accordingly, side leakage can be prevented or be made extremely low.

FIG. 28B and FIG. 28C illustrate other structure examples of transistors.

Each of a transistor 209 and a transistor 210 includes the conductive layer 221 functioning as a gate, the insulating layer 211 functioning as a first gate insulating layer, the semiconductor layer 231 including a channel formation region 231i and a pair of low-resistance regions 231n, the conductive layer 222a electrically connected to one of the pair of low-resistance regions 231n, the conductive layer 222b electrically connected to the other of the pair of low-resistance regions 231n, an insulating layer 225 functioning as a second gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned between at least the conductive layer 223 and the channel formation region 231i. Furthermore, an insulating layer 218 covering the transistor may be provided.

FIG. 28B illustrates an example of the transistor 209 where the insulating layer 225 covers the top and side surfaces of the semiconductor layer 231. The conductive layer 222a and the conductive layer 222b are electrically connected to the low-resistance regions 231n through openings provided in the insulating layer 225 and the insulating layer 215. One of the conductive layer 222a and the conductive layer 222b functions as a source, and the other functions as a drain.

Meanwhile, in the transistor 210 illustrated in FIG. 28C, the insulating layer 225 overlaps with the channel formation region 231i of the semiconductor layer 231 and does not overlap with the low-resistance regions 231n. The structure illustrated in FIG. 28C can be formed by processing the insulating layer 225 using the conductive layer 223 as a mask, for example. In FIG. 28C, the insulating layer 215 is provided to cover the insulating layer 225 and the conductive layer 223, and the conductive layer 222a and the conductive layer 222b are electrically connected to the low-resistance regions 231n through the openings in the insulating layer 215.

A connection portion 204 is provided in a region of the substrate 17b not overlapping with the substrate 13b. In the connection portion 204, the wiring 165 is electrically connected to the FPC 177 through a conductive layer 166 and a connection layer 242. The conductive layer 166 can be a conductive layer obtained by processing the same conductive film as the conductive film to be the conductive layer 171. The conductive layer 166 is exposed on the top surface of the connection portion 204. Thus, the connection portion 204 and the FPC 177 can be electrically connected to each other through the connection layer 242.

The material that can be used for the substrate 120 can be used for each of the substrate 17b and the substrate 13b.

The material that can be used for the adhesive layer 122 can be used for the adhesive layer 142.

As the connection layer 242, an anisotropic conductive film (ACF), an anisotropic conductive paste (ACP), or the like can be used.

At least part of the structure examples, the drawings corresponding thereto, and the like described in this embodiment can be combined with the other structure examples, the other drawings, and the like as appropriate.

At least part of this embodiment can be implemented in appropriate combination with the other embodiments described in this specification.

### Embodiment 5

In this embodiment, a light-emitting element that can be used for a display device of one embodiment of the present invention will be described with reference to drawings.

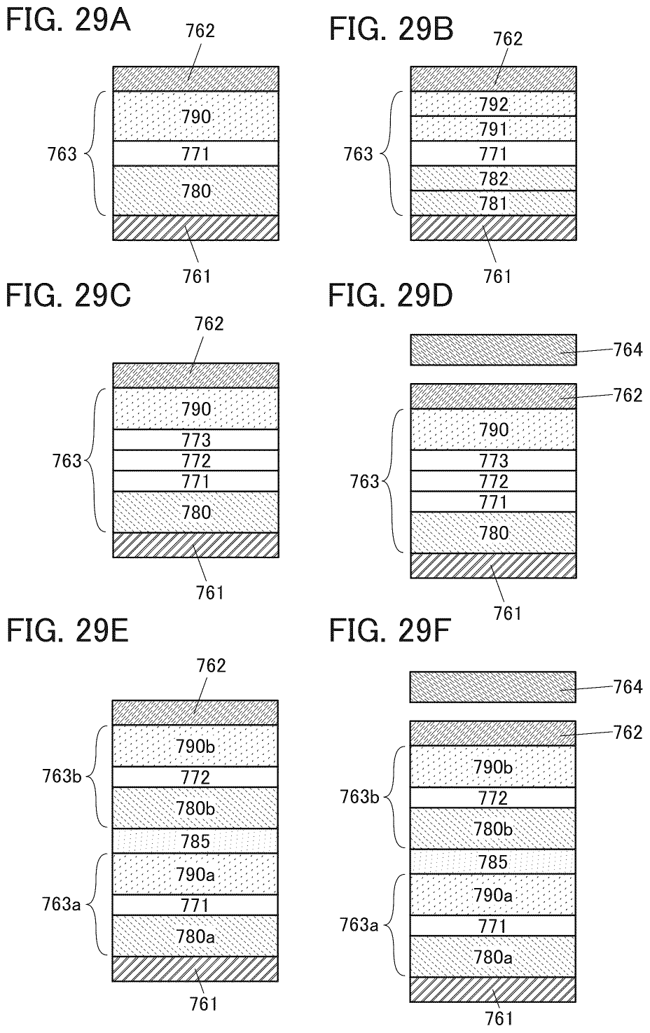

As illustrated in FIG. 29A, the light-emitting element includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance.

In the case where the lower electrode 761 is an anode and the upper electrode 762 is a cathode, the layer 780 includes one or more of a layer containing a substance having a high hole-injection property (a hole-injection layer), a layer containing a substance having a high hole-transport property (a hole-transport layer), and a layer containing a substance having a high electron-blocking property (an electron-blocking layer). Furthermore, the layer 790 includes one or more of a layer containing a substance having a high electron-injection property (an electron-injection layer), a layer containing a substance having a high electron-transport property (an electron-transport layer), and a layer containing a substance having a high hole-blocking property (a hole-blocking layer). In the case where the lower electrode 761 is a cathode and the upper electrode 762 is an anode, the structures of the layer 780 and the layer 790 are replaced with each other.

The structure including the layer 780, the light-emitting layer 771, and the layer 790, which is provided between the pair of electrodes, can function as a single light-emitting unit, and the structure in FIG. 29A is referred to as a single structure in this specification and the like.

FIG. 29B is a modification example of the EL layer 763 included in the light-emitting element illustrated in FIG. 29A. Specifically, the light-emitting element illustrated in FIG. 29B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layer structure, carriers can be efficiently injected to the light-emitting layer 771, and the efficiency of the recombination of carriers in the light-emitting layer 771 can be increased.

Note that structures in which a plurality of light-emitting layers (the light-emitting layer 771, a light-emitting layer 772, and a light-emitting layer 773) are provided between the layer 780 and the layer 790 illustrated in FIG. 29C and FIG. 29D are variations of the single structure. Although FIG. 29C and FIG. 29D illustrate the examples where three light-emitting layers are included, the light-emitting element with a single structure may include two or four or more light-emitting layers. In addition, the light-emitting element with a single structure may include a buffer layer between two light-emitting layers.

A structure where a plurality of light-emitting units (a light-emitting unit 763a and a light-emitting unit 763b) are connected in series with a charge-generation layer 785 (also referred to as an intermediate layer) therebetween as illustrated in FIG. 29E and FIG. 29F is referred to as a tandem structure in this specification and the like. Note that a tandem structure may be referred to as a stack structure. The tandem structure enables a light-emitting element capable of high-luminance light emission. Furthermore, the tandem structure can reduce the amount of current needed for obtaining the same luminance as compared with a single structure, and thus can improve the reliability.

Note that FIG. 29D and FIG. 29F illustrate examples where the display device includes a layer 764 overlapping with the light-emitting element. FIG. 29D illustrates an example where the layer 764 overlaps with the light-emitting element illustrated in FIG. 29C, and FIG. 29F illustrates an example where the layer 764 overlaps with the light-emitting element illustrated in FIG. 29E. In FIG. 29D and FIG. 29F, a conductive film transmitting visible light is used for the upper electrode 762 to extract light to the upper electrode 762 side.

One or both of a color conversion layer and a color filter (a coloring layer) can be used as the layer 764.

In FIG. 29C and FIG. 29D, light-emitting substances emitting light of the same color, or moreover, the same light-emitting substance may be used for the light-emitting layer 771, the light-emitting layer 772, and the light-emitting layer 773. For example, a light-emitting substance emitting blue light may be used for each of the light-emitting layer 771, the light-emitting layer 772, and the light-emitting layer 773. In a subpixel emitting blue light, blue light emitted from the light-emitting element can be extracted. In a subpixel emitting red light and a subpixel emitting green light, by providing a color conversion layer as the layer 764 illustrated in FIG. 29D, blue light emitted from the light-emitting element can be converted into light with a longer wavelength and thus red light or green light can be extracted. As the layer 764, both a color conversion layer and a coloring layer are preferably used. In some cases, part of light emitted from the light-emitting element is transmitted by the color conversion layer without being converted. When light transmitted by the color conversion layer is extracted through the coloring layer, light other than light of the intended color can be absorbed by the coloring layer, and color purity of light exhibited by a subpixel can be improved.

In FIG. 29C and FIG. 29D, light-emitting substances emitting light of different colors may be used for the light-emitting layer 771, the light-emitting layer 772, and the light-emitting layer 773. White light emission can be obtained when the light-emitting layer 771, the light-emitting layer 772, and the light-emitting layer 773 emit light of complementary colors. The light-emitting element with a single structure preferably includes a light-emitting layer containing a light-emitting substance emitting blue light and a light-emitting layer containing a light-emitting substance emitting visible light having a longer wavelength than blue light, for example.

A color filter may be provided as the layer 764 illustrated in FIG. 29D. When white light passes through the color filter, light of a desired color can be obtained.

In the case where the light-emitting element with a single structure includes three light-emitting layers, for example, a light-emitting layer containing a light-emitting substance emitting red (R) light, a light-emitting layer containing a light-emitting substance emitting green (G) light, and a light-emitting layer containing a light-emitting substance emitting blue (B) light are preferably included. The stacking order of the light-emitting layers can be RGB from the anode side or RBG from the anode side, for example. In that case, a buffer layer may be provided between R and G or between R and B.

For example, in the case where the light-emitting element with a single structure includes two light-emitting layers, the light-emitting element preferably includes a light-emitting layer containing a light-emitting substance emitting blue (B) light and a light-emitting layer containing a light-emitting substance emitting yellow (Y) light. Such a structure may be referred to as a BY single structure.

The light-emitting element emitting white light preferably contains two or more kinds of light-emitting substances. To obtain white light emission, two or more light-emitting substances may be selected such that their emission colors are complementary colors. For example, when an emission color of a first light-emitting layer and an emission color of a second light-emitting layer are complementary colors, the light-emitting element can be configured to emit white light as a whole. The same applies to a light-emitting element including three or more light-emitting layers.

Also in FIG. 29C and FIG. 29D, the layer 780 and the layer 790 may each independently have a stacked-layer structure of two or more layers as illustrated in FIG. 29B.

In FIG. 29E and FIG. 29F, light-emitting substances emitting light of the same color, or moreover, the same light-emitting substance may be used for the light-emitting layer 771 and the light-emitting layer 772. For example, in light-emitting elements included in subpixels emitting light of different colors, a light-emitting substance that emits blue light may be used for each of the light-emitting layer 771 and the light-emitting layer 772. In the subpixel emitting blue light, blue light emitted from the light-emitting element can be extracted. In the subpixel emitting red light and the subpixel emitting green light, by providing a color conversion layer as the layer 764 illustrated in FIG. 29F, blue light emitted from the light-emitting element can be converted into light with a longer wavelength and thus red light or green light can be extracted. As the layer 764, both a color conversion layer and a coloring layer are preferably used.

In the case where the light-emitting element having the structure illustrated in FIG. 29E or FIG. 29F is used for the subpixels emitting light of different colors, the subpixels may use different light-emitting substances. Specifically, in the light-emitting element included in the subpixel emitting red light, a light-emitting substance that emits red light can be used for each of the light-emitting layer 771 and the light-emitting layer 772. Similarly, in the light-emitting element included in the subpixel emitting green light, a light-emitting substance that emits green light can be used for each of the light-emitting layer 771 and the light-emitting layer 772. In the light-emitting element included in the subpixel emitting blue light, a light-emitting substance that emits blue light can be used for each of the light-emitting layer 771 and the light-emitting layer 772. A display device with such a structure includes a light-emitting element with a tandem structure and can be regarded as having an SBS structure. Thus, the display device can take advantages of both the tandem structure and the SBS structure. Accordingly, a light-emitting element being capable of high-luminance light emission and having high reliability can be obtained.

In FIG. 29E and FIG. 29F, light-emitting substances emitting light of different colors may be used for the light-emitting layer 771 and the light-emitting layer 772. White light emission can be obtained when the light-emitting layer 771 and the light-emitting layer 772 emit light of complementary colors. A color filter may be provided as the layer 764 illustrated in FIG. 29F. When white light passes through the color filter, light of a desired color can be obtained.

Although FIG. 29E and FIG. 29F illustrate examples where the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

In addition, although FIG. 29E and FIG. 29F illustrate the light-emitting element including two light-emitting units, one embodiment of the present invention is not limited thereto. The light-emitting element may include three or more light-emitting units. Note that a structure including two light-emitting units and a structure including three light-emitting units may be referred to as a two-unit tandem structure and a three-unit tandem structure, respectively.

In FIG. 29E and FIG. 29F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are replaced with each other, and the structures of the layer 780b and the layer 790b are also replaced with each other.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of manufacturing a light-emitting element with a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

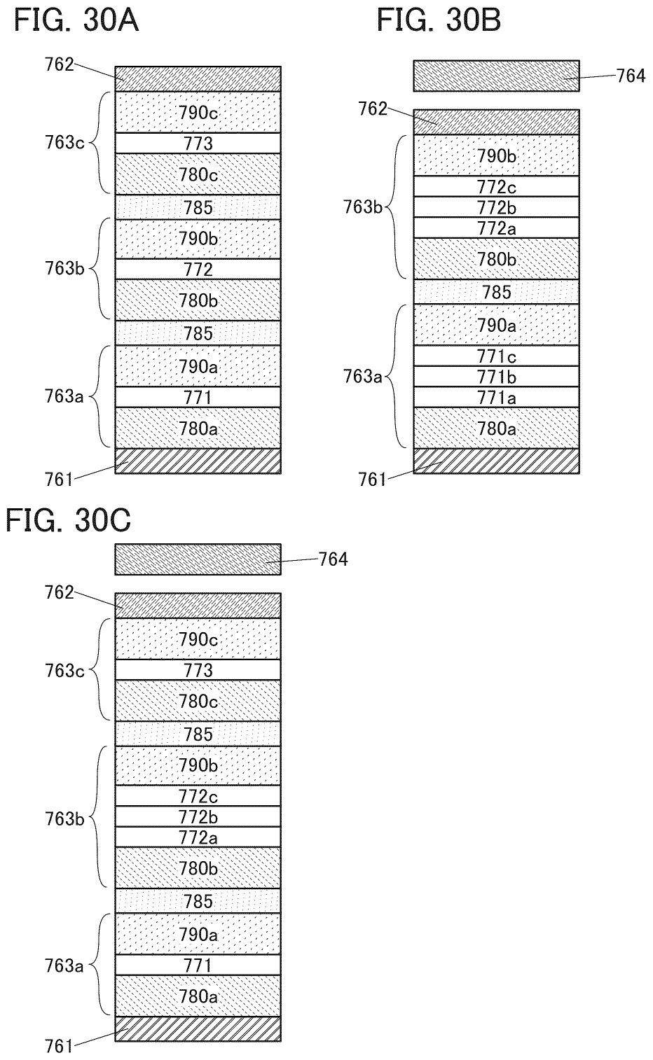

Structures illustrated in FIG. 30A to FIG. 30C can be given as examples of the light-emitting element with a tandem structure.

FIG. 30A illustrates a structure including three light-emitting units. In FIG. 30A, a plurality of light-emitting units (the light-emitting unit 763a, the light-emitting unit 763b, and a light-emitting unit 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 30A, the light-emitting layer 771, the light-emitting layer 772, and the light-emitting layer 773 preferably contain light-emitting substances that emit light of the same color. Specifically, the light-emitting layer 771, the light-emitting layer 772, and the light-emitting layer 773 can each contain a light-emitting substance that emits red (R) light (a so-called R\R\R three-unit tandem structure); the light-emitting layer 771, the light-emitting layer 772, and the light-emitting layer 773 can each contain a light-emitting substance that emits green (G) light (a so-called G\G\G three-unit tandem structure); or the light-emitting layer 771, the light-emitting layer 772, and the light-emitting layer 773 can each contain a light-emitting substance that emits blue (B) light (a so-called B\B\B three-unit tandem structure). Note that “a\b” means that a light-emitting unit containing a light-emitting substance that emits light of b is provided over a light-emitting unit containing a light-emitting substance that emits light of a with a charge-generation layer therebetween, where a and b represent colors.

In FIG. 30A, light-emitting substances emitting light of different colors may be used for some or all of the light-emitting layer 771, the light-emitting layer 772, and the light-emitting layer 773. Examples of a combination of emission colors for the light-emitting layer 771, the light-emitting layer 772, and the light-emitting layer 773 include blue (B) for two of them and yellow (Y) for the other; and red (R) for one of them, green (G) for another, and blue (B) for the other.

Note that the structure of the light-emitting unit is not limited to the structure illustrated in FIG. 30A. For example, a light-emitting element with a tandem structure may be employed where light-emitting units each including a plurality of light-emitting layers are stacked as illustrated in FIG. 30B. FIG. 30B illustrates a structure where two light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 30B, the light-emitting unit 763a is configured to emit white (W) light by selecting light-emitting substances for the light-emitting layer 771a, the light-emitting layer 771b, and the light-emitting layer 771c so that their emission colors are complementary colors. Furthermore, the light-emitting unit 763b is configured to emit white (W) light by selecting light-emitting substances for the light-emitting layer 772a, the light-emitting layer 772b, and the light-emitting layer 772c so that their emission colors are complementary colors. That is, the structure illustrated in FIG. 30B is a W\W two-unit tandem structure. Note that there is no particular limitation on the stacking order of the light-emitting substances having complementary emission colors. The practitioner can select the optimal stacking order as appropriate. Although not illustrated, a W\W\W three-unit tandem structure or a tandem structure with four or more units may be employed.

In the case where the light-emitting element with a tandem structure is used, the following structure can be given: a B\Y or Y\B two-unit tandem structure including a light-emitting unit that emits yellow (Y) light and a light-emitting unit that emits blue (B) light; an R·G\B or B\R·G two-unit tandem structure including a light-emitting unit that emits red (R) light and green (G) light and a light-emitting unit that emits blue (B) light; a B\Y\B three-unit tandem structure including a light-emitting unit that emits blue (B) light, a light-emitting unit that emits yellow (Y) light, and a light-emitting unit that emits blue (B) light in this order; a BYG\B three-unit tandem structure including a light-emitting unit that emits blue (B) light, a light-emitting unit that emits yellow green (YG) light, and a light-emitting unit that emits blue (B) light in this order; and a B\G\B three-unit tandem structure including a light-emitting unit that emits blue (B) light, a light-emitting unit that emits green (G) light, and a light-emitting unit that emits blue (B) light in this order, for example. Note that “a·b” means that one light-emitting unit contains a light-emitting substance that emits light of a and a light-emitting substance that emits light of b.

As illustrated in FIG. 30C, a light-emitting unit including one light-emitting layer and a light-emitting unit including a plurality of light-emitting layers may be used in combination.

Specifically, in the structure illustrated in FIG. 30C, a plurality of light-emitting units (the light-emitting unit 763a, the light-emitting unit 763b, and the light-emitting unit 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 30C, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellowish green (YG) light, and the light-emitting unit 763c is a light-emitting unit that emits blue (B) light can be employed.

Examples of the number of the stacked light-emitting units and the order of colors from the anode side include a two-unit structure of B and Y, a two-unit structure of B and a light-emitting unit X, a three-unit structure of B, Y, and B, and a three-unit structure of B, X, and B. Examples of the number of layers stacked in the light-emitting unit X and the order of colors from the anode side include a two-layer structure of R and Y, a two-layer structure of R and G, a two-layer structure of G and R, a three-layer structure of G, R, and G, and a three-layer structure of R, G, and R. Another layer may be provided between two light-emitting layers.

Next, materials that can be used for the light-emitting element are described.

A conductive film transmitting visible light is used for the electrode through which light is extracted, which is either the lower electrode 761 or the upper electrode 762. A conductive film reflecting visible light is preferably used for the electrode through which light is not extracted. In the case where a display device includes a light-emitting element that emits infrared light, it is preferable that a conductive film that transmits visible light and infrared light be used for the electrode through which light is extracted and a conductive film that reflects visible light and infrared light be used for the electrode through which light is not extracted.

A conductive film that transmits visible light may be used also for the electrode through which light is not extracted. In that case, the electrode is preferably placed between a reflective layer and the EL layer 763. In other words, light emitted from the EL layer 763 may be reflected by the reflective layer to be extracted from the display device.

As a material that forms the pair of electrodes of the light-emitting element, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide, indium tin oxide containing silicon, indium zinc oxide, and indium zinc oxide containing tungsten. Other examples of the material include an aluminum-containing alloy such as an alloy of aluminum, nickel, and lanthanum (Al—Ni—La), an alloy of silver and magnesium, and an alloy containing silver such as an alloy of silver, palladium, and copper (APC). Other example of the material include elements belonging to Group 1 or Group 2 of the periodic table, which are not exemplified above (e.g., lithium, cesium, calcium, or strontium), rare earth metals such as europium and ytterbium, an alloy containing any of these metals in appropriate combination, and graphene.

In addition, the light-emitting element preferably employs a microcavity structure. Therefore, one of the pair of electrodes included in the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

Note that the transflective electrode can have a stacked-layer structure of a conductive layer that can be used as a reflective electrode and a conductive layer that can be used as an electrode having a property of transmitting visible light (also referred to as a transparent electrode), for example.

The transparent electrode has a light transmittance higher than or equal to 40%. For example, an electrode having a visible light (light with a wavelength greater than or equal to 400 nm and less than 750 nm) transmittance higher than or equal to 40% is preferably used as the transparent electrode of the light-emitting element. The visible light reflectance of the transflective electrode is higher than or equal to 10% and lower than or equal to 95%, preferably higher than or equal to 30% and lower than or equal to 80%. The visible light reflectance of the reflective electrode is higher than or equal to 40% and lower than or equal to 100%, preferably higher than or equal to 70% and lower than or equal to 100%. These electrodes preferably have a resistivity of 1×10⁻² Ωcm or lower.

The light-emitting element includes at least the light-emitting layer. In addition, the light-emitting element may further include, as a layer other than the light-emitting layer, a layer containing a substance with a high hole-injection property, a substance with a high hole-transport property, a hole-blocking material, a substance with a high electron-transport property, an electron-blocking material, a substance with a high electron-injection property, a substance with a bipolar property (a substance with a high electron-transport property and a high hole-transport property), or the like. For example, the light-emitting element can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used for the light-emitting element, and an inorganic compound may also be contained. Each layer included in the light-emitting element can be formed by any of the following methods: an evaporation method (including a vacuum evaporation method), a transfer method, a printing method, an ink-jet method, a coating method, and the like.

The light-emitting layer contains one or more kinds of light-emitting substances. As the light-emitting substance, a substance exhibiting an emission color of blue, violet, bluish violet, green, yellowish green, yellow, orange, red, or the like is used as appropriate. Alternatively, a substance that emits near-infrared light can be used as the light-emitting substance.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material and an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use a substance with a high hole-transport property that can be used for the hole-transport layer and will be described later. As the electron-transport material, it is possible to use a substance with a high electron-transport property that can be used for the electron-transport layer and will be described later. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination is selected to form an exciplex that exhibits light emission whose wavelength overlaps with the wavelength of the lowest-energy-side absorption band of the light-emitting substance, energy can be transferred smoothly and light emission can be obtained efficiently. With this structure, the high efficiency, low-voltage driving, and long lifetime of the light-emitting element can be achieved at the same time.

The hole-injection layer is a layer injecting holes from an anode to a hole-transport layer and containing a substance with a high hole-injection property. Examples of the substance with a high hole-injection property include an aromatic amine compound and a composite material containing a hole-transport material and an acceptor material (electron-accepting material).

As the hole-transport material, it is possible to use a substance with a high hole-transport property that can be used for the hole-transport layer and will be described later.

As the acceptor material, an oxide of a metal belonging to any of Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is particularly preferable since it is stable in the air, has a low hygroscopic property, and is easy to handle. Alternatively, an organic acceptor material containing fluorine can be used. Alternatively, an organic acceptor material such as a quinodimethane derivative, a chloranil derivative, or a hexaazatriphenylene derivative can be used.

As the substance with a high hole-injection property, a material that contains a hole-transport material and the above-described oxide of a metal belonging to any of Group 4 to Group 8 of the periodic table (typically, molybdenum oxide) may be used, for example.

The hole-transport layer is a layer transporting holes, which are injected from the anode by the hole-injection layer, to the light-emitting layer. The hole-transport layer is a layer containing a hole-transport material. As the hole-transport material, a substance having a hole mobility greater than or equal to 1×10⁻⁶ cm²/Vs is preferable. Note that other substances can also be used as long as they have a property of transporting more holes than electrons. As the hole-transport material, a substance with a high hole-transport property, such as a π-electron rich heteroaromatic compound (e.g., a carbazole derivative, a thiophene derivative, or a furan derivative) or an aromatic amine (a compound having an aromatic amine skeleton), is preferable.

The electron-blocking layer is provided in contact with the light-emitting layer. The electron-blocking layer is a layer having a hole-transport property and containing a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer is a layer transporting electrons, which are injected from the cathode by the electron-injection layer, to the light-emitting layer. The electron-transport layer is a layer that contains an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, any of the following substances with a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a π-electron deficient heteroaromatic compound such as a nitrogen-containing heteroaromatic compound.

The hole-blocking layer is provided in contact with the light-emitting layer. The hole-blocking layer is a layer having an electron-transport property and containing a material that can block holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer is a layer injecting electrons from the cathode to the electron-transport layer and containing a substance with a high electron-injection property. As the substance with a high electron-injection property, an alkali metal, an alkaline earth metal, or a compound thereof can be used. As the substance with a high electron-injection property, a composite material containing an electron-transport material and a donor material (an electron-donating material) can also be used.

The difference between the LUMO level of the substance with a high electron-injection property and the work function value of the material used for the cathode is preferably small (specifically, smaller than or equal to 0.5 eV).

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato) lithium (abbreviation: Liq), 2-(2-pyridyl) phenolatolithium (abbreviation: LiPP), 2-(2-pyridyl)-3-pyridinolato lithium (abbreviation: LiPPy), 4-phenyl-2-(2-pyridyl) phenolatolithium (abbreviation: LiPPP), lithium oxide (LiOₓ), or cesium carbonate, for example. The electron-injection layer may have a stacked-layer structure of two or more layers. In the stacked-layer structure, for example, lithium fluoride can be used for the first layer and ytterbium can be used for the second layer.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, and a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), diquinoxalino [2,3-a: 2′,3′-c]phenazine (abbreviation: HATNA), 2,4,6-tris [3′-(pyridin-3-yl) biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

As described above, the charge-generation layer includes at least a charge-generation region. The charge-generation region preferably contains an acceptor material, and for example, preferably contains a hole-transport material and an acceptor material that can be used for the above-described hole-injection layer.

The charge-generation layer preferably includes a layer containing a substance with a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can be configured to contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (e.g., lithium oxide (Li₂O)). Alternatively, a material that can be used for the electron-injection layer can be favorably used for the electron-injection buffer layer.

The charge-generation layer preferably includes a layer containing a substance with a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper (II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from one another in some cases on the basis of the cross-sectional shapes, properties, or the like.

Note that the charge-generation layer may contain a donor material instead of an acceptor material. For example, the charge-generation layer may include a layer containing an electron-transport material and a donor material, which can be used for the electron-injection layer.

When the light-emitting units are stacked, provision of a charge-generation layer between the two light-emitting units can suppress an increase in driving voltage.

At least part of the structure examples, the drawings corresponding thereto, and the like described in this embodiment can be combined with the other structure examples, the other drawings, and the like as appropriate.

At least part of this embodiment can be implemented in appropriate combination with the other embodiments described in this specification.

### REFERENCE NUMERALS

10: electronic device, 11a: display device, 11aL: display device, 11aR: display device, 11b: display device, 11bL: display device, 11bR: display device, 12L: lens, 12R: lens, 12: lens, 13a: substrate, 13b: substrate, 14: half mirror, 15: housing, 16: substrate, 17a: substrate, 17b: substrate, 18: substrate, 20: eye, 27a: pixel, 27b: pixel, 34a: light, 34aA: light, 34aC: light, 34b: light, 34bB: light, 34bG: light, 34bR: light, 34c: light, 37a: display portion, 37b: display portion, 37c: display portion, 37: display portion, 38: region, 40: layer, 41a: display device, 41b: display device, 41L: display device, 41R: display device, 41: display device, 42a: gate driver circuit, 42b: gate driver circuit, 42: wearing tool, 43a: source driver circuit, 43b: source driver circuit, 44: light, 49L: camera, 49R: camera, 50: layer, 51: pixel circuit, 60: layer, 61A: light-emitting element, 61C: light-emitting element, 61: light-emitting element, 63B: light-emitting element, 63G: light-emitting element, 63R: light-emitting element, 100A: display device, 100a: display device, 100b: display device, 100C: display device, 100D: display device, 100E: display device, 100F: display device, 100G: display device, 100H: display device, 101: layer, 107: display portion, 110B: subpixel, light-emitting element, 110G: subpixel, light-emitting element, 110R: subpixel, light-emitting element, 110: pixel, 111B: pixel electrode, 111C: connection electrode, 111G: pixel electrode, 111R: pixel electrode, 111: pixel electrode, 112B: organic layer, 112G: organic layer, 112R: organic layer, 112: organic layer, 113: common electrode, 114: common layer, 120: substrate, 121: protective layer, 122: adhesive layer, 125: insulating layer, 126: resin layer, 128: layer, 140: connection portion, 142: adhesive layer, 164: circuit, 165: wiring, 166: conductive layer, 168: conductive layer, 171: conductive layer, 172A: EL layer, 172B: EL layer, 172C: EL layer, 172G: EL layer, 172R: EL layer, 173: conductive layer, 174: common layer, 176: IC, 177: FPC, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 255a: insulating layer, 255b: insulating layer, 255c: insulating layer, 256: plug, 261: insulating layer, 262: insulating layer, 263: insulating layer, 264: insulating layer, 265: insulating layer, 270A: layer, 270C: layer, 271: protective layer, 272: insulating layer, 273: protective layer, 274a: conductive layer, 274b: conductive layer, 274: plug, 275: plug, 278: insulating layer, 280: display module, 290: FPC, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 611: substrate, 611a: substrate, 611b: substrate, 612: layer, 612a: layer, 612b: layer, 613: substrate, 613a: substrate, 613b: substrate, 614: adhesive layer, 761: lower electrode, 762: upper electrode, 763a: light-emitting unit, 763b: light-emitting unit, 763c: light-emitting unit, 763: EL layer, 764: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 785: charge-generation layer, 790a: layer, 790b: layer, 790c: layer, 790: layer, 791: layer, 792: layer

1. An electronic device comprising:
a first display device;
a second display device;
a first half mirror; and
an eyepiece lens,
wherein the first display device comprises a plurality of first pixels,
wherein each of the plurality of first pixels comprises a light-emitting element exhibiting a first color,
wherein the second display device comprises a plurality of second pixels,
wherein each of the plurality of second pixels comprises a light-emitting element exhibiting a second color and a light-emitting element exhibiting a third color,
wherein the first color is one of green and blue, the second color is red, and the third color is the other of green and blue,
wherein the first display device is configured to display a first image,
wherein the second display device is configured to display a second image,
wherein the first display device is provided at such a position that the first image is reflected by the first half mirror and enters the eyepiece lens,
wherein the second display device is provided at such a position that the second image passes through the first half mirror and enters the eyepiece lens,
wherein the first image is presented through the eyepiece lens, and
wherein the second image is presented, through the eyepiece lens, to be superimposed on the first image.

2. An electronic device comprising:
a first display device;
a second display device;
a first half mirror; and
an eyepiece lens,
wherein the first display device comprises a plurality of first pixels,
wherein each of the plurality of first pixels comprises a light-emitting element exhibiting a first color,
wherein the second display device comprises a plurality of second pixels,
wherein each of the plurality of second pixels comprises a light-emitting element exhibiting a second color and a light-emitting element exhibiting a third color,
wherein the first color is one of green and blue, the second color is red, and the third color is the other of green and blue,
wherein the first display device is configured to display a first image,
wherein the second display device is configured to display a second image,
wherein the first display device is provided at such a position that the first image passes through the first half mirror and enters the eyepiece lens,
wherein the second display device is provided at such a position that the second image is reflected by the first half mirror and enters the eyepiece lens,
wherein the first image is presented through the eyepiece lens, and
wherein the second image is presented, through the eyepiece lens, to be superimposed on the first image.

3. The electronic device according to claim 1,
wherein a pixel density of the plurality of first pixels in the first display device is equal to a pixel density of the plurality of second pixels in the second display device.

4. The electronic device according to claim 1,
wherein a pixel density of the plurality of first pixels in the first display device is higher than or equal to 1000 ppi and lower than or equal to 20000 ppi.

5. The electronic device according to claim 1,
wherein the first display device comprises a plurality of first subpixels arranged in a matrix,
wherein the second display device comprises a plurality of second subpixels arranged in a matrix and a plurality of third subpixels arranged in a matrix,
wherein each of the plurality of first pixels comprises any one of the plurality of first subpixels,
wherein each of the plurality of second pixels comprises any one of the plurality of second subpixels and any one of the plurality of third subpixels,
wherein each of the plurality of first subpixels comprises the light-emitting element exhibiting the first color,
wherein each of the plurality of second subpixels comprises the light-emitting element exhibiting the second color,
wherein each of the plurality of third subpixels comprises the light-emitting element exhibiting the third color,
wherein a pixel density of the first subpixels in the first display device is higher than a pixel density of the second subpixels in the second display device, and
wherein in the second display device, the second subpixels and the third subpixels are alternately arranged in a horizontal direction and a vertical direction in a plan view.

6. The electronic device according to claim 2,
wherein the first display device comprises a plurality of first subpixels arranged in a matrix,
wherein the second display device comprises a plurality of second subpixels arranged in a matrix and a plurality of third subpixels arranged in a matrix,
wherein each of the plurality of first pixels comprises any one of the plurality of first subpixels,
wherein each of the plurality of second pixels comprises any one of the plurality of second subpixels and any one of the plurality of third subpixels,
wherein each of the plurality of first subpixels comprises the light-emitting element exhibiting the first color,
wherein each of the plurality of second subpixels comprises the light-emitting element exhibiting the second color,
wherein each of the plurality of third subpixels comprises the light-emitting element exhibiting the third color,
wherein a pixel density of the first subpixels in the first display device is higher than a pixel density of the second subpixels in the second display device, and
wherein in the second display device, the second subpixels and the third subpixels are alternately arranged in a horizontal direction and a vertical direction in a plan view.

7. The electronic device according to claim 5,
wherein the first image and the second image superimposed on each other are presented as a third image through the eyepiece lens, and
wherein in the third image, each of the plurality of first subpixels comprises a first region overlapping with one of the plurality of second subpixels, a second region overlapping with one of the plurality of third subpixels, and a third region overlapping neither the one of the plurality of second subpixels nor the one of the plurality of third subpixels.

8. An electronic device comprising:
a first display device;
a second display device;
a first half mirror; and
an eyepiece lens,
wherein the first display device comprises a first display portion,
wherein the second display device comprises a second display portion and a third display portion,
wherein the third display portion is provided to surround at least part of the second display portion in a plan view,
wherein the first display portion comprises a plurality of first pixels,
wherein each of the plurality of first pixels comprises a light-emitting element exhibiting a first color,
wherein the second display portion comprises a plurality of second pixels,
wherein each of the plurality of second pixels comprises a light-emitting element exhibiting a second color and a light-emitting element exhibiting a third color,
wherein the third display portion comprises a plurality of third pixels,
wherein each of the plurality of third pixels comprises a light-emitting element exhibiting the first color, a light-emitting element exhibiting the second color, and a light-emitting element exhibiting the third color,
wherein the first color is one of green and blue, the second color is red, and the third color is the other of green and blue,
wherein a pixel density of the plurality of third pixels in the third display portion is lower than a pixel density of the plurality of first pixels in the first display portion and a pixel density of the plurality of second pixels in the second display portion,
wherein the first display portion is configured to display a first image,
wherein the second display portion is configured to display a second image,
wherein the third display portion is configured to display a third image,
wherein the first display device is provided at such a position that the first image is reflected by the first half mirror and enters the eyepiece lens,
wherein the second display device is provided at such a position that the second image and the third image pass through the first half mirror and enter the eyepiece lens,
wherein the first image is presented through the eyepiece lens,
wherein the second image is presented, through the eyepiece lens, to be superimposed on the first image,
wherein the third image is presented through the eyepiece lens, and
wherein the third image presented through the eyepiece lens is presented in a region surrounding the first image presented through the eyepiece lens and the second image presented through the eyepiece lens.

9. The electronic device according to claim 2,
wherein the first display device comprises a first display portion,
wherein the second display device comprises a second display portion and a third display portion,
wherein the third display portion is provided to surround at least part of the second display portion in a plan view,
wherein the first display portion comprises the plurality of first pixels,
wherein the second display portion comprises the plurality of second pixels,
wherein the third display portion comprises a plurality of third pixels,
wherein each of the plurality of third pixels comprises a light-emitting element exhibiting the first color, a light-emitting element exhibiting the second color, and a light-emitting element exhibiting the third color,
wherein a pixel density of the plurality of third pixels in the third display portion is lower than a pixel density of the plurality of first pixels in the first display portion and a pixel density of the plurality of second pixels in the second display portion,
wherein the first display portion is configured to display the first image,
wherein the second display portion is configured to display the second image,
wherein the third display portion is configured to display a third image,
wherein the second display device is provided at such a position that the second image and the third image are reflected by the first half mirror and enter the eyepiece lens,
wherein the third image is presented through the eyepiece lens, and
wherein the third image presented through the eyepiece lens is presented in a region surrounding the first image presented through the eyepiece lens and the second image presented through the eyepiece lens.

10. The electronic device according to claim 8,
wherein the pixel density of the plurality of first pixels in the first display portion is higher than or equal to 1000 ppi and lower than or equal to 20000 ppi, and
wherein the pixel density of the plurality of third pixels in the third display portion is higher than or equal to 50 ppi and lower than 1000 ppi.

11. The electronic device according to claim 2,
wherein a pixel density of the plurality of first pixels in the first display device is equal to a pixel density of the plurality of second pixels in the second display device.

12. The electronic device according to claim 2,
wherein a pixel density of the plurality of first pixels in the first display device is higher than or equal to 1000 ppi and lower than or equal to 20000 ppi.

13. The electronic device according to claim 6,
wherein the first image and the second image superimposed on each other are presented as a third image through the eyepiece lens, and
wherein in the third image, each of the plurality of first subpixels comprises a first region overlapping with one of the plurality of second subpixels, a second region overlapping with one of the plurality of third subpixels, and a third region overlapping neither the one of the plurality of second subpixels nor the one of the plurality of third subpixels.

14. The electronic device according to claim 9,
wherein the pixel density of the plurality of first pixels in the first display portion is higher than or equal to 1000 ppi and lower than or equal to 20000 ppi, and
wherein the pixel density of the plurality of third pixels in the third display portion is higher than or equal to 50 ppi and lower than 1000 ppi.
